(19) United States
(12) Patent Application Publication
(10) Pub. No.: US 2015/0295058 A1
(43) Pub. Date: Oct. 15, 2015

(54) THIN-FILM TRANSISTOR AND MANUFACTURING METHOD THEREFOR

(71) Applicant: KABUSHIKI KAISHA KOBE SEIKO SHO (KOBE STEEL, LTD.), Kobe-shi, Hyogo (JP)

(72) Inventors: Shinya Morita, Kobe-shi (JP); Mototaka Ochi, Kobe-shi (JP); Hiroshi Goto, Kobe-shi (JP); Toshihiro Kugimiya, Kobe-shi (JP); Kenta Hirose, Kobe-shi (JP)

(73) Assignee: KABUSHIKI KAISHA KOBE SEIKO SHO (KOBE STEEL, LTD.), Kobe-shi, Hyogo (JP)

(21) Appl. No.: 14/439,570

(22) PCT Filed: Dec. 27, 2013
(86) PCT No.: PCT/JP2013/085112

§ 371 Date: Apr. 29, 2015

(30) Foreign Application Priority Data
Dec. 28, 2012 (JP) 2012-288945

(51) Int. Cl. H01L 29/45; H01L 21/44; H01L 21/46; H01L 29/786; H01L 29/66

(52) U.S. Cl. CPC H01L 29/45; H01L 29/7869; H01L 29/78636; H01L 29/78696; H01L 29/66969; H01L 21/46; H01L 21/44

(57) ABSTRACT

Provided is a back-channel etch type thin-film transistor (TFT) without an etch stopper layer, wherein an oxide semiconductor of the TFT has excellent resistance to an acid etchant and stress stability. The oxide semiconductor layer is a laminate having a first layer comprising tin, indium, and gallium or zinc, and oxygen, and a second layer comprising one or more elements selected from a group consisting indium, zinc, tin and gallium; and oxygen. The TFT is formed, in the following order, a gate insulator film, the second semiconductor layer and the first semiconductor layer; and having a value in a cross section in the lamination direction of the TFT, as determined by [100×(the first layer thickness of directly below a source-drain electrode end−a center portion thickness of the first layer)/the first layer thickness of directly below the source-drain electrode end], of not more than 5%.

### TECHNICAL FIELD

The present invention relates to a thin-film transistor (TFT) to be used in display devices such as liquid crystal displays and organic EL displays; and a manufacturing method of the thin-film transistor.

### BACKGROUND ART

As compared with widely used amorphous silicon (a-Si), amorphous (non-crystalline) oxide semiconductors have high carrier mobility (also called as field-effect mobility, which may hereinafter be referred to simply as “mobility”), a wide optical band gap, and film formability at low temperatures, and therefore, have highly been expected to be applied for next generation displays which are required to have large sizes, high resolution, and high-speed drives; resin substrates having low heat resistance; and others.

Among the oxide semiconductors, an amorphous oxide semiconductor consisting of indium (In), gallium (Ga), zinc (Zn), and oxygen (O) (In—Ga—Zn—O, which may hereinafter be referred to as “IGZO”), and an amorphous oxide semiconductor consisting of indium (In), zinc (Zn), tin (Sn), and oxygen (O) (In—Zn—Sn—O, which may hereinafter be referred to as “IZTO”) have been used because of their high carrier mobility.

There are two types in thin film transistors of bottom-gate structure comprising an oxide semiconductor; one is an etch stop (ESL) type with an etch stopper layer 8 as shown in FIG. 1A, while the other is a back channel etch (BCE) type without an etch stopper layer as shown in FIG. 1B.

The BCE-type TFT, without an etch stopper layer, depicted in FIG. 1B is superior in terms of productivity because formation of an etch stopper layer is not necessary in its fabrication process.

There is a problem, however, in the fabrication process of the BCE-type TFT as described in the following. A wet etchant for example an acid-based etching solution including phosphoric acid, nitric acid, and acetic acid, is used for processing a source-drain electrode formed on top of the oxide semiconductor layer. A surface of the oxide semiconductor layer being subjected to the wet etchant is etched or damaged so that the TFT characteristics of the oxide semiconductor may be deteriorated.

The aforementioned IGZO, for example, shows an high solubility to inorganic acid based wet etchants which are used to wet etch source-drain electrodes, and is extremely easily etched by the inorganic acid based wet etchant solutions. If the IGZO film is dissolved in the wet etching process of the source-drain electrode, fabrication of TFT then becomes difficult, and the TFT characteristics are deteriorated.

In an attempt to suppress the damage to the oxide semiconductor layer of the BCE-type TFT, technologies of Patent Documents 1 to 3 listed below have been proposed for example. These prior arts propose to suppress the damage to the oxide semiconductor layer by forming a sacrificial layer (or a recessed part) between the oxide semiconductor layer and the source-drain electrode. It is necessary, however, to increase numbers of processing steps in order to form such a sacrificial layer (or a recessed part). Further, non-patent Literature Document 1 shows removing a damaged layer from the surface of the oxide semiconductor layer. It is difficult, however, to uniformly remove such a damaged layer.

### PRIOR ART DOCUMENTS

### Patent Document

Patent Document 1: Japanese Patent Laid-open Publciation No. 2012-146956
Patent Document 2: Japanese Patent Laid-open Publciation No. 2011-54812
Patent Document 3: Japanese Patent Laid-open Publciation No. 2009-4787

### Non-Patent Literature Document

Non-patent Literature Document 1: C.-J. Kim et al., Electrochem. Solid-State Lett., 12 (4), H95-H97 (2009)

### SUMMARY OF THE INVENTION

### Problems to be Solved by the Invention

The present invention has been made under the circumstances described above, and one object of the present invention is to provide a BCE-type thin film transistor, without an etch stopper layer, having; high field-effect mobility; and excellent resistance to stresses such as voltage application and light irradiation, which is represented by a small variation in the threshold voltage before and after applying the stresses.

### Means for Solving the Problems

One thin film transistor of the present invention, which can solve the above-mentioned problems, is comprising at least; a gate electrode, a gate insulator film, an oxide semiconductor layer, a source-drain electrode, and a passivation film to protect the source-drain electrode, on a substrate in this order, the oxide semiconductor layer is a laminate comprising: a first oxide semiconductor layer consisting of Sn; In; and at least one of Ga and Zn; and O; and a second oxide semiconductor layer consisting of one or more kinds of element selected from a group consisting of In, Zn, Sn, and Ga; and O. The second oxide semiconductor layer is formed on the gate insulator film. The first oxide semiconductor layer is formed between the second oxide semiconductor layer and the passivation film. Alternatively, the first oxide semiconductor layer is formed between the second oxide semiconductor layer and the source-drain electrode. The thin film transistor is characterized in that a value in a cross section in the lamination direction, as determined by [100×(the thickness of the first oxide semiconductor layer directly below a source-drain electrode end−the thickness in the center portion of the first oxide semiconductor layer)/the thickness of the first semiconductor layer directly below the source drain electrode end] is equal to or smaller than 5%.

In a preferred embodiment of the present invention, binding energy of the most intensive peak among oxygen is spectra is in a range from 529.0 eV to 531.3 eV when a surface of the first oxide semiconductor layer is subjected to X-ray photoelectron spectroscopy.

In a preferred embodiment of the present invention, the first oxide semiconductor layer comprises Sn in an amount of 9 atomic % or larger and 50 atomic % or smaller relative to the total amount of all the metal elements in the oxide semiconductor layer.

In a preferred embodiment of the present invention, the first oxide semiconductor layer is composed of In, Ga, Zn, Sn, and O, wherein the contents of respective metal elements relative to the total amount of In, Ga, Zn, and Sn; In: larger than or equal to 15 atomic % and smaller than or equal to 25 atomic %; Ga: larger than or equal to 5 atomic % and smaller than or equal to 20 atomic %; Zn: larger than or equal to 40 atomic % and smaller than or equal to 60 atomic %; and Sn: larger than or equal to 5 atomic % and smaller than or equal to 25 atomic %.

In a preferred embodiment of the present invention, the first oxide semiconductor layer comprises Zn, and a concentration of Zn (in atomic %) at a surface is 1.0 to 1.6 times of the content of Zn (in atomic %) in the first oxide semiconductor layer.

In a preferred embodiment of the present invention, the source-drain electrode comprises a conductive oxide layer which is in direct contact to the oxide semiconductor layer.

In a preferred embodiment of the present invention, the source-drain electrode is composed of a laminate structure consisting of a conductive oxide layer and one metal layer (referred to X layer, including an Al alloy layer) or more comprising one or more kinds of element selected from a group consisting of Al, Cu, Mo, Cr, Ti, Ta, and W.

In a preferred embodiment of the present invention, the metal layer (X layer) is composed of a laminate structure consisting of a metal layer (X2 layer) comprising at least one kind of element selected from a group consisting of Mo, Cr, Ti, Ta, and W; and a metal layer (X1 layer) comprising one or more kinds of layer selected from a group consisting of a pure Al layer, an Al alloy layer, a pure Cu layer, and a Cu alloy layer; in this order from the side of the oxide semiconductor layer.

In a preferred embodiment of the present invention, the metal layer (X layer) is composed of a laminate structure consisting of a metal layer (X1 layer) comprising one or more kinds of layer selected from a group consisting of a pure Al layer, an Al alloy layer, a pure Cu layer, and a Cu alloy layer; and a metal layer (X2 layer) comprising one or more kinds of element selected from a group consisting of Mo, Cr, Ti, Ta, and W; and in this order from the side of the oxide semiconductor layer.

In a preferred embodiment of the present invention, the metal layer (X layer) is composed of a laminate structure consisting of a metal layer (X2 layer) comprising one or more kinds of element selected from a group consisting of Mo, Cr, Ti, Ta, and W; a metal layer (X1 layer) comprising one or more kinds of layer selected from a group consisting of a pure Al layer, an Al alloy layer, a pure Cu layer, and a Cu alloy layer; and a metal layer (X2 layer) comprising one or more kinds of element selected from a group consisting of Mo, Cr, Ti, Ta, and W; in this order from the side of the oxide semiconductor layer.

In a preferred embodiment of the present invention, the Al alloy layer comprises one or more kinds of element selected from a group consisting of Ni, Co, Cu, Ge, Ta, Mo, Hf, Zr, Ti, Nb, W, and a rare-earth element in an amount of 0.1 atomic % or more.

In a preferred embodiment of the present invention, the conductive oxide layer comprises one or more kinds of element selected from a group consisting of In, Ga, Zn, and Sn; and O.

In a preferred embodiment of the present invention, the source-drain electrode is composed of a laminate structure consisting of the barrier metal layer comprising one or more kinds of element selected from a group consisting of Mo, Cr, Ti, Ta, and W; and an Al alloy layer, in this order from the side of the oxide semiconductor layer.

In a preferred embodiment of the present invention, a barrier metal of the source-drain electrode comprises pure Mo or a Mo alloy.

In a preferred embodiment of the present invention, the Al alloy layer of the source-drain electrode comprises one or more kinds of element selected from a group consisting of Ni and Co in a total amount of 0.1 to 4 atomic %.

In a preferred embodiment of the present invention, the Al alloy layer of the source-drain electrode comprises one or more kinds of element selected from a group consisting of Cu and Ge in a total amount of 0.05 to 2 atomic %.

In a preferred embodiment of the present invention, the Al alloy layer of the source-drain electrode further comprises one or more kinds of element selected from a group consisting of Nd, Y, Fe, Ti, V, Zr, Nb, Mo, Hf, Ta, Mg, Cr, Mn, Ru, Rh, Pd, Ir, Pt, La, Gd, Tb, Dy, Sr, Sm, Ge, and Bi.

The present invention also encompasses a manufacturing method of the thin film transistor. The manufacturing method is characterized in that the source-drain electrode formed on the oxide semiconductor layer is patterned by using an acid based etchant solution, followed by an oxidation treatment for at least a part of the oxide semiconductor layer which is subjected to the acid based etchant solution, and then the passivation film is formed.

In a preferred embodiment, the oxidation treatment is at least one of a heat treatment and a N₂O plasma treatment, and more preferably both of the heat treatment and the N₂O plasma treatment.

In a preferred embodiment, the heat treatment is conducted at a temperature higher than or equal to 130° C. and lower than or equal to 400° C.

### Effects of the Invention

The present invention can provide a BCE-type thin film transistor having a first oxide for semiconductor layer, comprising Sn, which is excellent in terms of uniformity in thickness, state of the surface, and stress stability. These features are derived from an oxidation treatment conducted to the first oxide semiconductor layer that has been subjected to an acid based etchant solution for forming a source-drain electrode in the course of the manufacturing process of the BCE-type TFT.

Further, the present invention also provides a manufacturing method in which a source-drain electrode can be formed by using wet etching, which can readily provides a display device of superior properties at a low cost.

Furthermore, the TFT according to the present invention can sufficiently reduce the manufacturing cost as well since numbers of masks to be formed in the course of fabrication process of the TFT are small due to the absence of an etch stopper layer as described above. It is also possible to reduce the size of TFT by adopting a BCE-type TFT as it does not have an overlapping portion of an etch stopper layer and a source-drain electrode, which is inevitable in an ESL-type TFT.

### BRIEF DESCRIPTION OF DRAWING

FIG. 1A is a schematic cross-sectional view for explaining an embodiment of a conventional ESL-type thin film transistor, and FIG. 1B is a schematic cross-sectional view for explaining an embodiment of a BCE-type thin film transistor of the present invention.

FIGS. 2A to 2E are schematic cross-sectional structures of source-drain electrodes in thin film transistors of the present invention.

FIG. 3 is a schematic cross-sectional view for explaining a thin film transistor of the present invention.

FIG. 4 is a FE-SEM (Field Emission Scanning Electron Microscope) picture of an inventive example of the present invention. FIG. 4B is a magnified view of an area indicated by a broken line frame in FIG. 4A.

FIG. 5 is a FE-SEM picture of a comparative example of the present invention. FIG. 5B is a magnified view of an area indicated by a broken line frame in FIG. 5A.

FIG. 6 shows a result of stress stability test of a comparative example.

FIG. 7 shows a result of stress stability test of an inventive example.

FIG. 8 shows a result of X-ray Photoelectron Spectroscopy (XPS) of an example.

FIG. 9 shows XPS (X-ray Photoelectron Spectra) of sample 1 for analyses in an example.

FIG. 10 shows XPS (X-ray Photoelectron Spectra) of sample 2 for analyses in an example.

FIG. 11 shows results of XPS (X-ray Photoelectron spectroscopy) depth analyses of chemical compositions of an oxide semiconductor layer in an example.

FIG. 12 shows a relation between heat treatment temperature and Zn concentration ratio in the surface layer in an example.

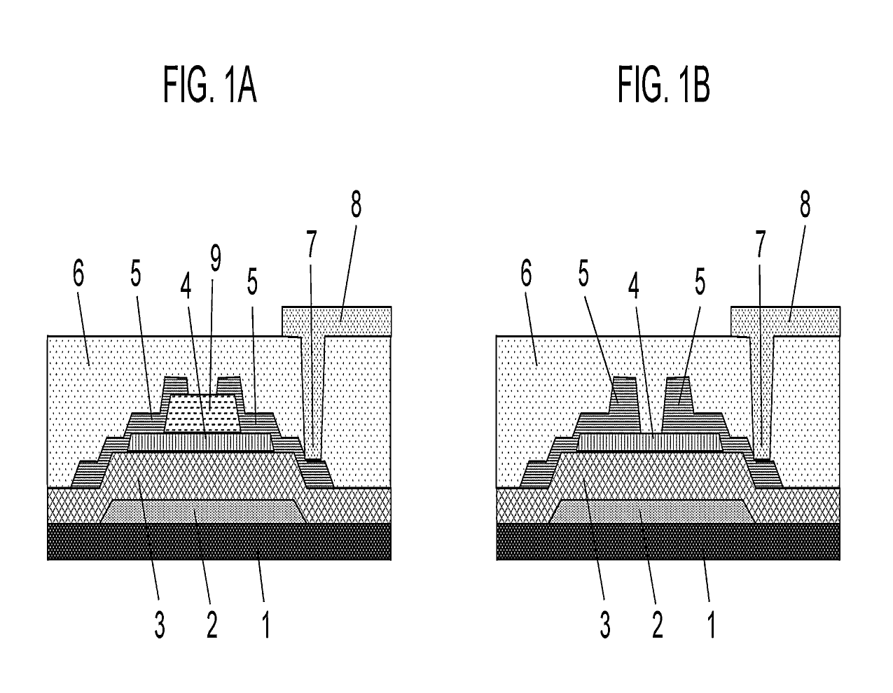

### MODE FOR CARRYING OUT THE INVENTION

The present inventors carried out intensive studies in order to solve the problem regarding BCE-type TFT and completed the invention by finding that the desired object is effectively accomplished by;
including particularly Sn in the first oxide semiconductor layer which is consisting a laminate with the second oxide semiconductor layer and is subjected to an acid-based etchant solution in the course of forming the source-drain electrode; and
carrying out an oxidation treatment as described below for at least a part of the first oxide semiconductor layer which is subjected to the acid-based etchant solution after the formation of the source-drain electrode (i.e., after the acid etching);
to successfully remove contaminants and damages caused by the wet acid etching and hence to obtain a TFT having the oxide semiconductor layer of uniform thickness as well as excellent stress stability.

Firstly, compositions and structure of the oxide semiconductor layer of the present invention are explained.

The oxide semiconductor according to the present invention is a laminate structure consisting of a first oxide semiconductor layer and a second oxide semiconductor layer, and is characterized in that the first oxide semiconductor layer which is subjected to acid based etchant solution in the course of forming a source-drain electrode comprising Sn and In (Sn in particular) as essential components.

Each of the first oxide semiconductor layer and the second oxide semiconductor layer is described below.

### (First Oxide Semiconductor Layer)

Due to the presence of Sn, it is possible to suppress etching of the first oxide semiconductor layer by acid based etchant solution, and to maintain the surface smoothness of the first oxide semiconductor layer. The first oxide semiconductor layer further comprises In, and even further comprises at least one kind of Ga and Zn.

Content of Sn (relative to the total amount of all the metal elements in the first oxide semiconductor layer; the same holds for contents of other metal elements) is to be controlled to preferably 5 atomic % or more, more preferably 9 atomic % or more, even more preferably 15 atomic % or more, and still more preferably 19 atomic % or more, in the first oxide semiconductor layer in order to sufficiently exert the effect.

If the amount of Sn contained in the first oxide semiconductor layer is excessively large, on the other hand, there may be a case in which the stress stability is deteriorated and the etching rate to a wet etchant solution for the oxide semiconductor is decreased. Sn is thus to be contained in an amount of preferably 50 atomic % or less, more preferably 30 atomic % or less, even more preferably 28 atomic % or less, and still more preferably 25 atomic % or less.

The first oxide semiconductor layer is subjected to an acid-based wet etchant solution in the course of forming the source-drain electrode. However, etching of the first oxide semiconductor layer is suppressed by including Sn in the layer as described above. More specifically, etching rate of the oxide semiconductor layer in an acid-based etchant solution is decreased to 1 \acute{Å}/sec or less, leading to realization a TFT having a 5% or smaller difference between the thickness of the oxide semiconductor layer directly below an end of a source-drain electrode and the thickness in the center portion of the oxide semiconductor layer as determined by (100×[(the thickness of the oxide semiconductor layer directly below a source-drain electrode end−the thickness in the center portion of the oxide semiconductor layer)/the thickness of the semiconductor layer directly below the source-drain electrode end]). The “center portion of the oxide semiconductor layer” stated here means a midpoint of the shortest line joining an end of the source electrode and an end of the drain electrode. If the etching is not uniform and the difference in the thickness is larger than 5%, deviation of chemical composition by different etching rates between metal elements is caused within the oxide semiconductor. The difference in the thickness is thus preferably smaller than or equal to 3%, and is most preferably 0%, having no difference.

The first oxide semiconductor layer further comprises In. In is an element effective to reduce electrical resistance of an oxide semiconductor layer. In order to effectively exert the effect, In is to be contained in an amount of preferably 1 atomic % or more, more preferably 3 atomic % or more, and even more preferably 5 atomic % or more. It is still more preferably 15 atomic % or more. On the other hand, if the contained amount of In is excessively large, there may be a case in which the stress stability is deteriorated. In is thus to be contained in an amount of preferably 25 atomic % or less, more preferably 23 atomic % or less, and even more preferably 20 atomic % or less.

The first oxide semiconductor layer further comprises at least one kind of Ga and Zn.

Ga is an element effective to suppress generation of oxygen deficiency and improve stress stability. In order to effectively exert the effect, Ga is to be contained in an amount of preferably 5 atomic % or more, more preferably 10 atomic % or more, and even more preferably 15 atomic % or more. On the other hand, if the contained amount of Ga is excessively large, there may be a case in which the mobility is decreased due to relative decrease of In and Sn which play a role of conduction path for electrons in the transistor. Ga is thus to be contained in an amount of preferably 40 atomic % or less, more preferably 30 atomic % or less, even more preferably 25 atomic % or less, and still more preferably 20 atomic % or less.

Zn is an element which influences wet etching rate and contribute to improving wet etching properties of the oxide semiconductor layer. Zn is also an effective element to make amorphous structure of the oxide semiconductor stable and to secure stable and good switching operation of TFTs. In order to sufficiently exert these effects, Zn is to be contained in an amount of preferably 35 atomic % or more, more preferably 40 atomic % or more, and even more preferably 45 atomic % or more. If the contained amount of Zn is excessively large, on the other hand, etching rate of such oxide semiconductors excessively increases in wet etchant solutions for processing oxide semiconductors, which makes patterning the oxide semiconductor layers into a desired shape difficult. Further, there may be a case in which the oxide semiconductor thin film is crystallized or the stress stability is deteriorated due to relative decrease of In and Sn. Zn is thus to be contained in an amount of preferably 65 atomic % or less, more preferably 60 atomic % or less.

In—Ga—Zn—Sn—O (IGZTO) or the like may be exemplified as the first oxide semiconductor layer.

The first oxide semiconductor layer is the In—Ga—Zn—Sn—O (IGZTO), being composed of In, Ga, Zn, Sn, and O, and when the total amount of In, Ga, Zn, and Sn is 100 atomic %, the contents of each of the elements are preferably;
In: larger than or equal to 15 atomic % and smaller than or equal to 25 atomic %;
Ga: larger than or equal to 5 atomic % and smaller than or equal to 20 atomic %;
Zn: larger than or equal to 40 atomic % and smaller than or equal to 60 atomic %; and
Sn: larger than or equal to 5 atomic % and smaller than or equal to 25 atomic %.

As for the material components constituting the first oxide semiconductor layer, it is preferable to set it to an appropriate range with a consideration of balance among respective metal element in order to effectively secure desirable properties. The first oxide semiconductor is composed of, for example, the In:Ga:Sn ratio ranging from 1:1:1 to 2:2:1 in atomic ratio.

### (Second Oxide Semiconductor Layer)

The second oxide semiconductor layer consists of one or more kinds of element selected from the group consisting of In, Zn, Sn, and Ga; and O.

As for the metals, In, Zn, Sn, and Ga, constituting the second oxide semiconductor, the ratio among the respective metals is not particularly limited, so long as it is in the range where oxides containing these metals have amorphous phase and show semiconductor characteristics. As explained above regarding metal elements which may be contained in the first oxide semiconductor layer, contents of the metal elements affect mobility and adaptability to wet etching process. It is preferable to appropriately control the contents of the metal elements in the second oxide semiconductor layer, accordingly. For example, it is desirable that the first and second oxide semiconductor layers have a similar etching rate to each other for wet etching. The chemical compositions of the oxide semiconductors may thus be adjusted so that the etching rates are nearly equal (etching rate ratio of 0.1 to 4) to each other.

The second oxide semiconductor layer includes In—Zn—Sn—O (IZTO), ITO, IGZO, Sn—Ga—Zn—O (TGZO), or the like.

The most preferable combination of the first and second oxide semiconductors is In—Ga—Zn—Sn—O (IGZTO) film for the first oxide semiconductor layer and IZTO film for the second oxide semiconductor layer.

Thickness of the first oxide semiconductor layer is not particularly limited. The thickness of the first oxide semiconductor layer is preferably controlled to greater than or equal to 20 nm, and more preferably greater than or equal to 30 nm. On the other hand, the thickness of the first oxide semiconductor layer is preferably smaller than or equal to 50 nm, and more preferably smaller than or equal to 40 nm.

Thickness of the second oxide semiconductor layer is not particularly limited either. The thickness of the second oxide semiconductor layer is preferably controlled to greater than or equal to 5 nm, and more preferably greater than or equal to 10 nm, from the view point of securing the in-plane characteristics of the substrate (TFT characteristics such as mobility, S value, and Vₜₕ) in a stable manner. On the other hand, the thickness of the second oxide semiconductor layer is preferably smaller than or equal to 100 nm, and more preferably smaller than or equal to 50 nm, from the point of view to securing the good processability of the oxide semiconductor layer.

The upper limit of total thickness of the oxide semiconductor layer consisting of the second oxide semiconductor layer and the first oxide semiconductor layer is for example preferably smaller than or equal to 100 nm, and more preferably smaller than or equal to 50 nm. The lower limit of the total thickness may not be particularly specified as long as the effects of each of the oxide semiconductor layers can be exerted.

The first oxide semiconductor layer comprises Zn, and a concentration of Zn at a surface (referred to as “Zn concentration in the surface layer” hereinafter; in atomic %) is preferably 1.0 to 1.6 times of the content of Zn in the first oxide semiconductor layer (in atomic %). An explanation regarding the Zn concentration in the surface layer of the first oxide semiconductor layer is given below including the background to control it in that manner.

Chemical composition of the first oxide semiconductor layer is liable to fluctuate in the surface layer by being damaged due to an acid-based etching solution used to form the source-drain electrode in the course of manufacturing the TFT. Because Zn oxides are particularly soluble to the acid-based etching solution, Zn concentration in the surface layer of the first oxide semiconductor layer is liable to be reduced. According to a study by the present inventors, it was found that the low concentration of Zn in the surface of the first oxide semiconductor layer can generate much oxygen deficiencies on the surface of the first oxide semiconductor layer leading to deterioration of the TFT characteristics such as mobility and reliability.

The present inventors studied Zn concentration at a surface (contacting to the passivation film) of the first oxide semiconductor layer (Zn concentration in surface layer), aiming to suppress the generation of oxygen deficiencies, accordingly. As a result of the study, the Zn concentration in the surface layer was found preferably 1.0 times or more of the concentration in the first oxide semiconductor layer in order to sufficiently annihilate the oxygen deficiencies. The ratio of the Zn concentration in the surface layer to that in the first oxide semiconductor layer ((Zn concentration in the surface layer/Zn content in the first oxide semiconductor layer) in atomic ratio. The ratio is referred to “Zn concentration ratio in the surface layer” hereinafter) is preferably larger than or equal to 1.1, and more preferably equal to or larger than 1.2. The larger the Zn concentration ratio in the surface layer is, the more preferable as the effect is enhanced. Considering the preferable manufacturing conditions of the present invention, however, the upper limit is equal to or smaller than 1.6. The Zn concentration ratio in the surface layer is preferably equal to or smaller than 1.5, and more preferably equal to or smaller than 1.4. The Zn concentration ratio in the surface layer may be measured by a method described below in Examples. The Zn concentration ratio in the surface layer can be realized by carrying out an oxidation treatment described below and driving Zn to the surface of the first oxide semiconductor layer. Specifically, the oxidation treatment includes a heat treatment and a N₂O plasma treatment, particularly a heat treatment. A heat treatment at higher temperatures is preferable as described below.

In the present invention, Sn is particularly contained in the first oxide semiconductor layer in order to secure the resistance to acid-based etchant solutions used in the process of forming the source-drain electrode as described above. However, that is not enough to satisfactory secure stress stability as compared to EST-type TFTs having an etch stopper layer. Therefore, an oxidation treatment is further carried out in the manufacturing process of the TFT after forming a source-drain electrode and before forming a passivation film in the present invention as explained in detail below.

By the oxidation treatment, a surface of the first oxide semiconductor layer, which has been damaged by being subjected to an acid-based etchant solution, is restored to the state prior to the acid etching.

The details are as follows. During the wet etching (acid etching) for forming the source-drain electrode, contaminations such as OH and C are included in the oxide semiconductor layer, the first oxide semiconductor layer in particular, which is subjected to the acid-base etchant solution. These contaminations such as OH and C are liable to generate oxygen deficiencies which form trap levels and deteriorate the TFT characteristics. The issue of oxygen deficiency is, however, circumvented by carrying out the oxidation treatment after the wet etching, by which the contaminations are substituted for oxygen. The state of the surface prior to the wet etching is restored by the removal of OH and C, and satisfactory TFT characteristics can be obtained in the BCE-type TFT.

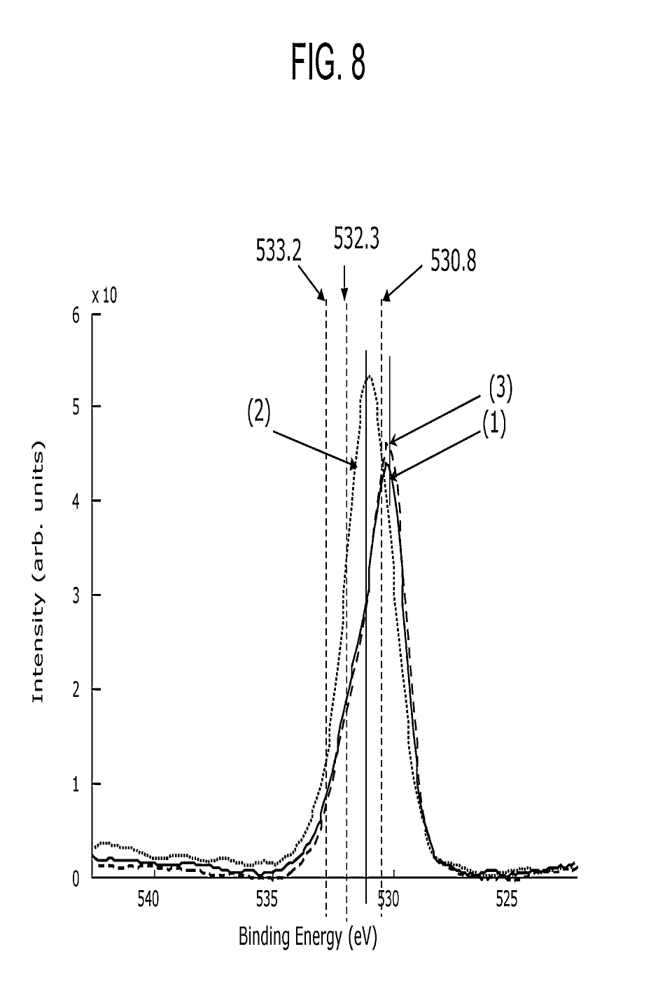

As explained below in detail in Examples (FIG. 8 shown below), the present inventors confirmed the above-mentioned mechanism by observing the surface of the oxide semiconductor layer at respective stages of “immediately after forming the layer (as-deposited oxide semiconductor),” “after the acid etching,” and “after the oxidation treatment” by X-ray photoelectron spectroscopy (XPS) and comparing the binding energy of O1s spectrum peak of the highest intensity.

The binding energy of O1s (oxygen 1s) spectrum peak is located at about 530.8 eV, as tagged (1) in FIG. 8 shown below, immediately after forming the oxide semiconductor (as-deposited layer). When the acid etching is conducted onto the as-deposited oxide semiconductor layer which is not subjected to the oxidation treatment and is equivalent to a conventional TFT fabrication process, the O1s spectrum peak of the surface of the oxide semiconductor layer shifts from about 530.8 eV of the as-deposited state to 532.3 eV which is representing oxygen deficiency as tagged (2) in FIG. 8 shown below. The peak shift indicates that oxygen of metal oxides constituting the oxide semiconductor layer is substituted by the adsorbed OH and C, resulting in oxygen-deficient state of the surface of the oxide semiconductor layer.

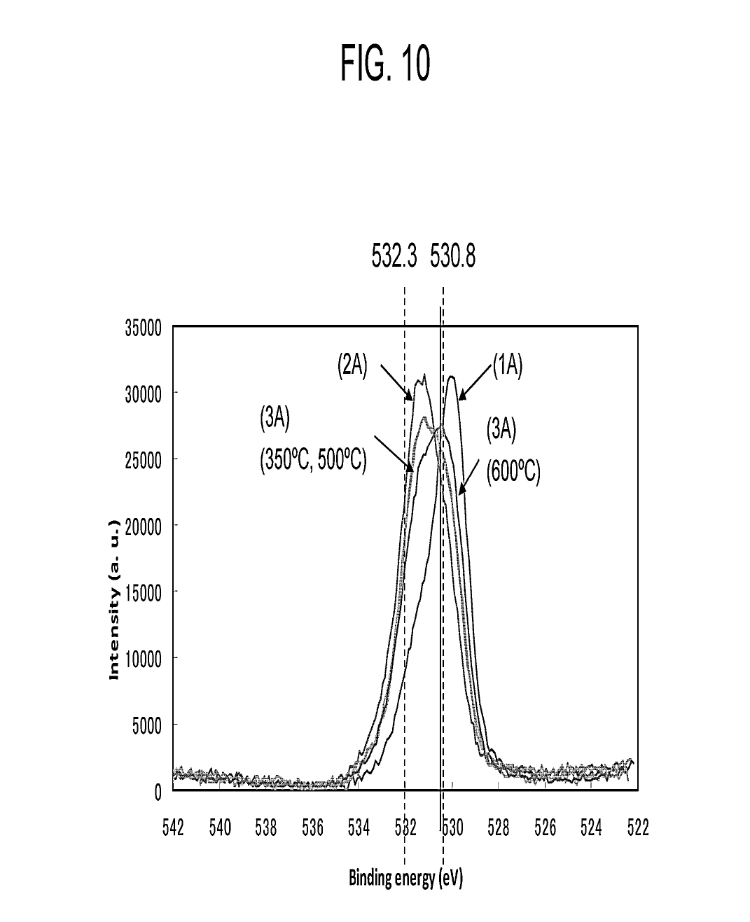

When the surface of the first oxide semiconductor of the present invention is further subjected to the oxidation treatment after the acid etching, on the other hand, the binding energy of the O1s spectrum peak, as tagged (3) in FIG. 10 shown below, is smaller than that of the surface just after the acid etching. The spectrum peak is thus shifted toward the position of the as-deposited surface. The O1s spectrum peak is located in a range, for example, from 529.0 to 531.3 eV after the oxidation treatment. It is noted here that the spectrum peak is located at about 530.8 eV (within a range of 530.8±0.5 eV) which is approximately the same position of the O1s spectrum peak immediately after the formation of the oxide semiconductor layer as shown in an Example described below. It is thus considered that the oxidation treatment removed OH and C or the like as explained above and the surface of the oxide semiconductor layer restored the state prior to the wet etching.

The oxidation treatment includes at least either of a heat treatment and a N₂O plasma treatment. It is preferable to conduct both of the heat treatment and the N₂O plasma treatment. The order of the heat treatment and the N₂O plasma treatment is not particularly limited.

The heat treatment may be conducted under the following conditions. The environment of the heating includes water vapor atmosphere and oxygen atmosphere. The heat treatment is preferably conducted at a temperature higher than or equal to 130° C., more preferably 250° C. or higher, even more preferably 300° C. or higher, and still more preferably 350° C. or higher. On the other hand, excessively high heat treatment temperature is liable to deteriorate the source-drain electrode material. The heat treatment is thus preferably conducted at a temperature lower than or equal to 700° C., more preferably 650° C. or lower. From the viewpoint of circumventing the deterioration of the source-drain electrode material it is even more preferable to conduct the heat treatment at a temperature lower than or equal to 600° C. The holding time at the heating temperature (heating time) is preferably longer than or equal to 5 minutes, and more preferable 60 minutes or longer. Excessively long heating time deteriorates the productivity and more than certain effects cannot be expected. The heating time is thus preferably shorter than or equal to 120 minutes, and more preferably 90 minutes or shorter.

The N₂O plasma treatment is to be conducted under conditions of, for example, plasma power of 100 W, gas pressure of 133 Pa, treatment temperature of 200° C., and treatment time of 10 seconds to 20 minutes.

The TFT of the present invention comprises a laminate structure consisting of the first oxide semiconductor layer and the second oxide semiconductor. Other than that, structural elements are not particularly limited. The TFT may comprise at least, for example, a gate electrode, a gate insulator film, the oxide semiconductor layer, a source-drain electrode, and a passivation film. These structural elements including the gate electrode are not particularly limited as long as they are those usually used in the field of TFT. From the view point of assuredly enhancing the TFT characteristics, the structure of the source-drain electrode is to be preferably controlled as explained in the following.

If the source-drain electrode consists of pure Al, pure Mo, an Al alloy, or a Mo alloy, there may be a case in which a surface of the electrode or an end of an etched electrode is oxidized upon carrying out an oxidation treatment described below. Once the surface of the electrode is oxidized and an oxide is formed, there may be a case in which the TFT characteristics and the manufacturing process are negatively affected by, for example, deterioration of adhesion to a photo-resist and a passivation film and increase of contact resistance to pixel electrode. Further, a problem of discoloration may arise. Furthermore, electrical resistance between the oxide semiconductor layer and the source-drain electrode is liable to increase when an end of electrode is oxidized. It has been found out by a study of the present inventors that such an oxidized end of the electrode material is liable to increase the S value of I_{d}-V_{g}characteristics and deteriorate the TFT characteristics (the static characteristics in particular).

For the reasons described above, the present inventors found that the deterioration such as an increase of S value can be suppressed by making the source-drain electrode to comprise an conductive oxide layer which shows little change in terms of properties such as electrical property by oxidation and to be in direct contact to the oxide semiconductor layer. As a result, it was also found out that the optical stress stability can be improved without deteriorating the static characteristics (S value in particular) of TFT.

The material constituting the conductive oxide layer is not particularly limited as long as it is an oxide which is electrically conductive and soluble to an acid-based etchant solution, for example PAN-based etchant solution used in an Example described below, used in the formation of the source-drain electrode.

The conductive oxide layer is preferably comprising one or more kinds of element selected from a group consisting of In, Ga, Zn, and Sn; and O. Typical conductive oxide is, for example, ITO or IZO. ZAO (Al added ZnO), GZO (Ga added ZnO) or the like may be adopted. The conductive oxide layer is preferably ITO (In—Sn—O) or IZO (In—Zn—O).

The conductive oxide layer is preferably in amorphous structure. Polycrystalline material is liable to cause problems such as generation of etching residue in a wet etching process or difficulty in performing etching, which an amorphous material hardly causes.

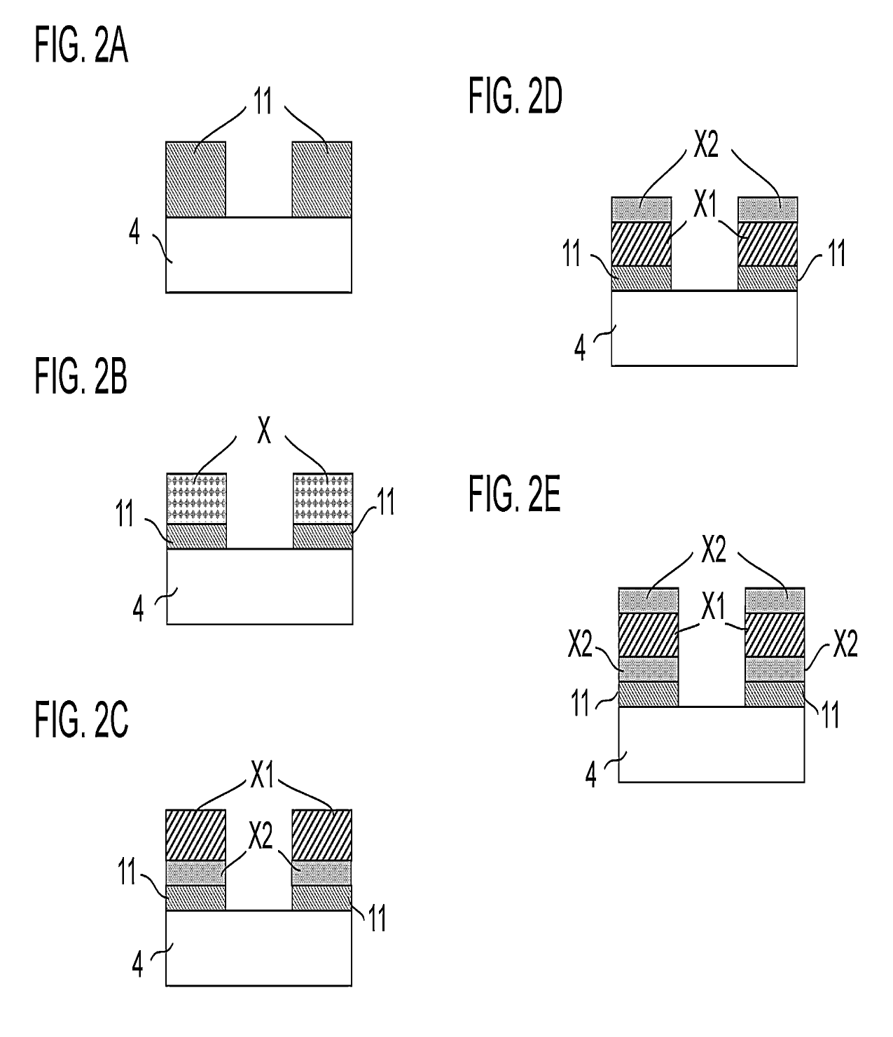

The source-drain electrode 5 formed on the oxide semiconductor layer 4 may be a single layer of conductive oxide layer 11 as schematically illustrated in FIG. 2A or a laminate structure comprising a conductive oxide layer 11 as shown below in FIGS. 2B to 2E.

Thickness of the conductive oxide layer constituting the source-drain electrode may be 10 to 500 nm if the conductive oxide is a single layer while it may be 10 to 100 nm if the conductive oxide is a laminate with X layer described in detail below.

As schematically illustrated in FIG. 2B, the source-drain electrode may be a laminate structure comprising the conductive oxide layer 11 and one or more metal layer (X layer, tagged as X) including one or more kinds of element selected from a group consisting of Al, Cu, Mo, Cr, Ti, Ta, and W. The conductive oxide layer is preferably in direct contact to the first oxide semiconductor layer in both cases where the source-drain electrode is a single layer and a laminate.

Conductive oxides in general have high electrical resistivity as compared to metals. From the point of view of decreasing electrical resistance of the source-drain electrode, it is recommended to make the source-drain electrode a laminate of the conductive oxide layer and a metal layer (X layer) as described above.

The expression “including one or more kind of element” means that it includes a metal layer including a pure metal of the element and an alloy having the elements as the main constituent (50 atomic % or more, for example).

It is preferable to include one or more kinds of layer selected from a group consisting of a pure Al layer, an Al alloy layer, a pure Cu layer, and a Cu alloy layer as the metal layer (X1 layer, hereinbelow the pure Al layer and the Al alloy layer are occasionally referred to as “Al-based layer” collectively, and the pure Cu layer and the Cu alloy layer are occasionally referred to as “Cu-based layer” collectively) because the electrical resistance of the source-drain electrode can be decreased.

By including an Al alloy layer as the X1 layer, prevention of hillock formation due to heating of the layer, improvement of the corrosion resistance, and improvement of electrical connection of the source-drain electrode and pixel electrode such as ITO and IZO can be implemented. The Al alloy layer preferably comprises one or more kinds of element selected from a group consisting of Ni, Co, Cu, Ge, Ta, Mo, Hf, Zr, Ti, Nb, W, and a rare-earth element in an amount of 0.1 atomic % or more, more preferably 0.5 atomic % or more, and even more preferably 0.6 atomic % or more, and the reminder being Al and inevitable impurities. The rare-earth element is an element group including Sc (scandium) and Y (yttrium) in addition to lanthanoid elements (a total of 15 elements from La with an atomic number of 57 to Lu with an atomic number of 71 in the periodic table).

It is preferable to use an appropriate Al alloy for the Al alloy layer depending on the purpose as described in the following (i) and (ii) in particular. (i) It is preferable to contain a rare-earth element such as Nd, La, and Y, or a refractory metal element such as Ta, Zr, Nb, Ti, Mo, and Hf in order to improve corrosion resistance and heat resistance of the Al alloy layer. The optimum amount of the element may be appropriately adjusted depending on wiring resistance and processing temperature in the course of manufacturing the TFT. (ii) It is preferable to contain Ni or Co in order to improve electrical contact of the Al alloy layer with an pixel electrode. The corrosion resistance and electrical contact of the Al alloy can be improved further by adding Cu or Ge which refines precipitates.

The X1 layer may be 50 to 500 nm in thickness, for example.

A metal layer (X2 layer) comprising one or more kinds of element selected from a group consisting of Mo, Cr, Ti, Ta, and W may also be included as the X layer. The X2 layer is generally referred to as a barrier metal (layer). The above-mentioned X2 layer contributes to the improvement of electrical connection as explained in detail below.

The X2 layer may be formed by interposing it between the conductive oxide layer and the X1 layer for the purposes of improving the adhesion and electrical connection to these layers as well as preventing interdiffusion.

Specifically, when a conductive oxide layer and an Al-based X1 layer are used for the source-drain electrode, an X2 layer may be interposed between the conductive oxide layer and the Al-based layer for the purpose of preventing generation of hillocks in the Al-based layer in the course of the heating process and improving the electrical connection to a pixel electrode such as ITO and IZO connected to the source-drain electrode in a subsequent processing step.

When a conductive oxide layer and a Cu-based X1 layer are used for the source-drain electrode, an X2 layer may be interposed between these layers for the purpose of suppressing oxidation of a surface of the Cu-based layer.

An X2 layer may be formed on both the side of the oxide semiconductor layer and the opposite side of the X1 layer as in an embodiment (III) described below.

The X2 layer (barrier metal layer) may be 50 to 500 nm in thickness, for example.

The X layer may be composed of just an X1 layer (in the form of a single layer or a laminate) or a combination of an X1 layer (in the form of a single layer or a laminate) and an X2 layer (in the form of a single layer or a laminate).

The source-drain electrode may be one of the following specific embodiments (I) to (III) when the X layer is a combination of X1 and X2 layers.
(I) An embodiment of a laminate structure having a conductive oxide layer 11, an X2 layer (tagged X2), and an X1 layer (tagged X1) in this order from the side of the oxide semiconductor layer 4 as illustrated in FIG. 2C.
(II) An embodiment of a laminate structure having a conductive oxide layer 11, an X1 layer (tagged X1), and an X2 layer (tagged X2) in this order from the side of the oxide semiconductor layer 4 as illustrated in FIG. 2D.
(III) An embodiment of a laminate structure having a conductive oxide layer 11, an X2 layer (tagged X2), an X1 layer (tagged X1), and an X2 layer (tagged X2) in this order from the side of the oxide semiconductor layer 4 as illustrated in FIG. 2E.

A barrier metal layer comprising one or more kinds of element selected from a group consisting of Mo, Cr, Ti, Ta, and W is generally adopted as the source-drain electrode. When a surface of the source-drain electrode (the surface on the opposite side of the substrate) is constituted of the barrier metal layer, however, the surface and an etched end of the electrode are oxidized to form a thick oxide film by the oxidation treatment, and the TFT characteristics (the static characteristics in particular) are liable to be deteriorated, and adhesion deterioration to the upper layer such as the passivation layer is liable to result in peeling off the layer. Additionally, there could be a following problem. A single layer of pure Mo or a laminate consisting of pure Mo, pure Al, and a pure Mo three-layer structure is generally used for the barrier metal layer. When such a layer is used for the source-drain electrode, residues of an oxide such as a Mo oxide could be generated on the surface of the source-drain electrode or on a part of the glass substrate which is not covered by the passivation layer as the oxide is dissolved into water in a water rinsing process in the course of fabrication of the source-drain electrode.

Such residues of the oxide, for example Mo oxide, not only causes to increase leakage current but also deteriorates adhesion between the source-drain electrode and the passivation film or a photoresist layer which are deposited on the source-drain electrode, leading to delamination of the passivation insulator film or the like.

For the aforementioned reasons, the present inventors found that the source-drain electrode may be appropriately a laminate consisting of a barrier metal layer such as a pure Mo layer and an Al alloy layer from the side of the oxide semiconductor layer. With such a laminate film, amount of the pure Mo exposed to rinsing water may be minimized in the course of fabrication process of the source-drain electrode. As a result, dissolution of the Mo oxide in the water rinsing process may be suppressed. Thickness of the barrier metal layer such as a pure Mo layer can also be reduced in the laminate structure, as compared to that of a single layer barrier metal constituting the source-drain electrode. This leads to suppression of the forming oxide at the interface with the oxide semiconductor and improvement of the light stress stability without deteriorating the TFT characteristics (without increasing the S value in particular).

The Al alloy layer of the source-drain electrode preferably comprises one or more kinds of element selected from a group consisting of Ni and Co (group A element) in a total amount of 0.1 to 4 atomic %. It also preferable comprises, instead of the group A element or along with the group A element, one or more kinds of element selected from a group consisting of Cu and Ge (group B element) in a total amount of 0.05 to 2 atomic %. Following is an explanation on the Al alloy layer.

A part of the surface of the source-drain electrode (the surface on the opposite side of the substrate) is direct contact to a transparent conductive oxide film such as ITO and IZO which is generally used for a pixel electrode. In case the surface of the source-drain electrode is pure Al, an insulator film of aluminum oxide is liable to be formed between the pure Al and the transparent conductive oxide film, deteriorating the ohmic contact and increasing the contact resistance at the interface.

The Al alloy layer constituting the surface of the source-drain electrode (the surface on the opposite side of the substrate) preferably comprises one or more kinds of element selected from a group consisting of Ni and Co (group A element) in the present invention. By containing the group A element, compounds of Ni or Co are precipitated at the interface between the Al alloy layer and the pixel electrode, which decreases electrical contact resistance at the interface with the transparent conductive oxide film. As a result of that, an upper barrier metal layer (pure Mo layer) of source-drain electrode consisting of the three-layer laminate of the pure Mo/a pure Al/a pure Mo may be omitted. The total contents of the group A elements is preferably 0.1 atomic % or more, more preferably 0.2 atomic % or more, and even more preferably 0.4 atomic % or more in order to exert the effect. Excessively high total amount of the group A element, on the other hand, increases electrical resistivity of the Al alloy layer. It is thus preferably 4 atomic % or less, more preferably 3.0 atomic % or less, and even more preferably 2.0 atomic %.

Cu and Ge, the group B elements, are effective to enhance corrosion resistance of the Al alloy film. Total content of the group B element is preferably more than or equal to 0.05 atomic % in order to exert the effect. It is more preferably 0.1 atomic % or more, and even more preferably 0.2 atomic % or more. Excessively high total content of the group B element, on the other hand, increases electrical resistivity of the Al alloy film. It is thus preferably 2 atomic % or less, more preferably 1 atomic % or less, and even more preferably 0.8 atomic % or less.

The Al alloy layer may further comprise at least one kind of element (group C element) selected from a group (group C) consisting of Nd, Y, Fe, Ti, V, Zr, Nb, Mo, Hf, Ta, Mg, Cr, Mn, Ru, Rh, Pd, Ir, Pt, La, Gd, Tb, Dy, Sr, Sm, Ge, and Bi.

The group C elements are effective to enhance heat resistance of the Al alloy layer and to prevent generation of hillocks on its surface. Total content of the group C element is preferably more than or equal to 0.1 atomic % in order to exert the effect. It is more preferably 0.2 atomic % or more, and even more preferably 0.3 atomic % or more. Excessively high total content of the group C element, on the other hand, increases electrical resistivity of the Al alloy layer. It is thus preferably 1 atomic % or less, more preferably 0.8 atomic % or less, and even more preferably 0.6 atomic % or less.

Among the group C elements, preferred element is at least one kind of element selected from a group consisting of Nd, La, and Gd.

The Al alloy layer includes those comprising the group A element, the group A element and the group B element, the group A element and the group C element, the group A element and the group B element and the group C element, the group B element, and the group B element and the group C element, the reminder Al and inevitable impurities.

Thickness of the barrier metal layer is preferably more than or equal to 3 nm from the viewpoint of thickness uniformity. It is more preferably 5 nm or more, and even more preferably 10 nm or more. Excessively thick barrier metal layer, however, increases the proportion of the barrier metal in the total thickness and hence electrical resistivity of the interconnection. It is thus preferably 100 nm or less, more preferably 80 nm or less, and even more preferably 60 nm or less.

Thickness of the Al alloy layer is preferably more than or equal to 100 nm from the viewpoint of lowering electrical resistance of the interconnection. It is more preferably 150 nm or more, and even more preferably 200 nm or more. Excessively thick Al alloy layer, however, arises a problem such as increasing process time of the film deposition and etching and hence production cost. It is thus preferably 1000 nm or less, more preferably 800 nm or less, and even more preferably 600 nm or less.

Ratio of thickness of the barrier metal layer to the total film thickness is preferably more than or equal to 0.02 from the viewpoint of blocking property of the barrier metal. It is more preferably 0.04 or more, and even more preferably 0.05 or more. Excessively large ratio of thickness, however, increases electrical resistance of the interconnection. It is thus preferably 0.5 or less, more preferably 0.4 or less, and even more preferably 0.3 or less.

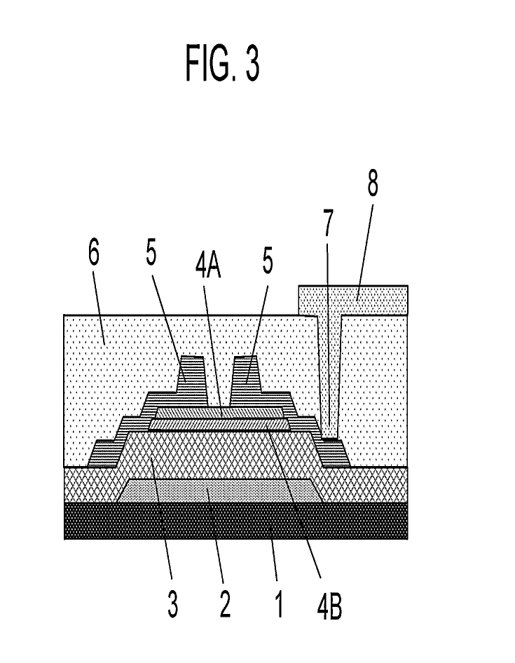

Referring to FIG. 3, embodiments of a fabrication process, including the oxidation treatment, of the TFT of the present invention are described in the following. FIG. 3 and the following fabrication process demonstrate one example of preferred embodiments of the present invention, but it is not intended that the present invention be limited thereto.

As shown in FIG. 3, a gate electrode 2 and a gate insulator film 3 are formed on the substrate 1, and a second oxide semiconductor layer 4B is formed thereon. On the second oxide semiconductor layer 4B, a first oxide semiconductor layer 4A is formed. A source-drain electrode 5 is formed further thereon. A passivation film (insulating film) 6 is formed thereon, and a transparent conductive film (not shown in FIG. 3) is electrically connected to the drain electrode 5 through a contact hole 7.

The method of forming the gate electrode 2 and the gate insulator layer 3 on the substrate 1 is not particularly limited, and any of the methods usually used can be employed. The kinds of the gate electrode 2 and the gate insulator film 3 are not particularly limited, and those which are widely used can be adopted. For example, metals having low electrical resistivity, such as Al and Cu, refractory metals having high heat resistance, such as Mo, Cr and Ti, and their alloys, can preferably be used for the gate electrode 2. Typical examples of the gate insulator film may include a silicon oxide layer (SiO₂), a silicon nitride layer (SiN), and a silicon oxynitride layer (SiON). In addition, oxides such as Al₂O₃ and Y₂O₃, and their laminates may also be used.

Subsequently, the oxide semiconductor layer (the second oxide semiconductor layer 4B and the first oxide semiconductor layer 4A from a side of the substrate) is deposited.

The second oxide semiconductor layer 4B and the first oxide semiconductor layer 4A may preferably be formed by a sputtering method (DC sputtering method or RF sputtering method) using a sputtering target (which may hereinafter be referred to as the “target”). The sputtering method requires no great effort to form a thin film having excellent uniformity in terms of composition or film thickness in the film surface. The second oxide semiconductor layer 4B and the first oxide semiconductor layer 4A can also be formed by a chemical film-formation method such as a coating method.

As a target to be used in the sputtering method, there may preferably be used a sputtering target containing the elements described above and having the same composition as that of a desired oxide, thereby making it possible to form a thin film showing small deviation of composition and having the same composition as that of the desired oxide.

Specifically, as the target for depositing the second oxide semiconductor layer 4B, an oxide target constituted of oxides of one or more kinds of metal element selected from a group consisting of In, Zn, Sn, and Ga, containing the elements described above and having the same composition as that of a desired oxide can be used.

As the target for depositing the first oxide semiconductor layer 4A, an oxide target constituted of oxides of metals of Sn, In; and one or more kinds of element selected from a group consisting of Ga and Zn, and having the same composition as that of a desired oxide can be used. Alternatively, the formation of the layer may also be carried out by a combinatorial sputtering method in which two targets having different compositions are simultaneously discharged. Each of the targets as described above can be produced, for example, by a powder sintering method.

The second oxide semiconductor layer 4B and the first oxide semiconductor layer 4A may preferably be formed successively, while keeping under vacuum, by the sputtering method. This is because exposure to air in the formation of the oxide semiconductor layers leads to the attachment of water or organic substances in the air to the thin film surface, which leads to the contamination (quality failure).

The sputtering may preferably be carried out under the conditions as follows. Substrate temperature is set to a range of approximately from room temperature to 200° C. Additive amount of oxygen may appropriately be controlled according to the configuration of a sputtering system and the composition of the target so that the deposited oxide layer shows characteristics of a semiconductor. The additive amount of oxygen may preferably be controlled by the addition of oxygen so that the carrier concentration of the semiconductor becomes approximately from 10¹⁵ to 10¹⁶ cm⁻³.

The gas pressure during the film deposition may preferably be in a range of approximately from 1 to 3 mTorr. It is recommended to set the input power to about 200 W or higher.

After the deposition of the oxide semiconductor layer (4A and 4B) as described above, the oxide semiconductor layer (4A and 4B) is subjected to wet etching and then patterning. After the patterning, heat treatment (pre-annealing) may preferably be carried out for the purpose of improving the quality of the oxide semiconductor layer (4A and 4B), which leads to an increase in the on-state current and field-effect mobility as the transistor characteristics and an improvement in the transistor performance. The pre-annealing conditions may be, for example, such that the temperature is from about 250° C. to about 400° C. and the duration is from about 10 minutes to about 1 hour, in an air or steam atmosphere.

After the pre-annealing, a source-drain electrode 5 may be formed. The kind of the source-drain electrode 5 is not particularly limited, and those which have widely been used can be employed. The source-drain electrode may be formed by magnetron sputtering, followed by patterning by photolithography and wet etching or dry etching. As an acid-based etchant solution is used for patterning formation of the source-drain electrode 5 in the present invention, an Al alloy, pure Mo, a Mo alloy or the like is preferably adopted for the source-drain electrode 5. Further, as described above, the source-drain electrode 5 preferably comprise a conductive oxide layer and the conductive oxide layer is preferably in direct contact to the oxide semiconductor layer 4 from the view point of securing the superior TFT characteristics. The source-drain electrode 5 may be a single conductive oxide layer, or a laminate of the conductive oxide layer and the X layer (either a single X1 layer or a combination of X1 and X2 layers).

The source-drain electrode 5 consisting of a metal thin film may be formed by way of depositing the metal thin film using, for example, a magnetron sputtering method followed by pattering via photolithography and acid wet etching using an acid-based etchant solution. The source-drain electrode 5 consisting of a single film of a conductive oxide layer 11 may be formed by way of depositing the conductive oxide layer using, as for the formation of the oxide semiconductor layer 4, a magnetron sputtering method followed by pattering via photolithography and acid wet etching using an acid-based etchant solution. When the source-drain electrode 5 is a laminate consisting of a conductive oxide layer and an X layer (a metal film), the source-drain electrode may be formed by laminating a single layer of the conductive oxide layer and an X layer (either a single X1 layer or a combination of X1 and X2 layers), followed by pattering via photolithography and acid wet etching using an acid-based etchant solution. The source-drain electrode may be etched by a dry etching method.

When the source-drain electrode 5 is a laminate film consisting of a barrier metal layer and an Al alloy layer, the source-drain electrode may be formed by way of depositing each of the metal thin film using, for example, a magnetron sputtering method followed by pattering via photolithography and acid wet etching using an acid-based etchant solution.

Next, the oxidation treatment is carried out as described in detail hereinabove. Then, the passivation layer 6 is formed on the oxide semiconductor layer 4A and source-drain electrode 5 by a CVD (Chemical Vapor Deposition) method. For the passivation layer 6, a silicon nitride (SiN) film, a silicon oxide (SiO₂) film, and silicon oxynitride (SiON) film, or a laminate of these films can be used. The passivation layer 6 may also be formed using a sputtering method.

Then, according to a conventional method, a transparent conductive film 8 is electrically connected to the drain electrode 5 through the contact hole 7. The kinds of the transparent conductive film and drain electrode are not particularly limited, and there can be used those which have usually been used.

Numbers of masks to be formed in the course of fabrication process of TFTs are decreased because the TFT according to the present invention does not have an etch stopper layer. The manufacturing cost can be sufficiently reduced, accordingly.

The present application claims the benefit of priority based on Japanese Patent Application No. 2012-288945 filed on Dec. 28, 2012. The entire contents of the specification of the Japanese Patent Application No. 2012-288945 filed on Dec. 28, 2012 are incorporated herein by reference.

### EXAMPLES

The present invention is described hereinafter more specifically by way of Examples, but the present invention is not limited to the following Examples. The present invention can be put into practice after appropriate modifications or variations within a range meeting the gist described above and below, all of which are included in the technical scope of the present invention.

### Example 1

### [Fabrication of TFT of the Present Inventive Example]

Thin film transistors shown in FIG. 3 were fabricated based on a method as described above, and their TFT characteristics (stress stability) were evaluated.

First, a Mo thin film of 100 nm in thickness as a gate electrode 2 and SiO₂ film of 250 nm in thickness as a gate insulator film 3 were successively deposited on a glass substrate 1 (“EAGLE XG” available from Corning Inc, having a diameter of 100 mm and a thickness of 0.7 mm). The gate electrode 2 was deposited using a pure Mo sputtering target by a DC sputtering method under the conditions: deposition temperature, room temperature; sputtering power, 300 W; carrier gas, Ar; gas pressure, 2 mTorr. Further, the gate insulator layer 3 was formed by a plasma CVD method under the conditions: carrier gas, a mixed gas of SiH₄ and N₂O; plasma power, 300 W; and deposition temperature, 350° C.

Next, a laminate of oxide semiconductor layers 4B and 4A was deposited as follows. The second oxide semiconductor layer 4B (In—Zn—Sn—O of In:Zn:Sn=20:56.7:23.3 in atomic % ratio) was deposited on a gate insulator film 3. Then, a first oxide semiconductor layer 4A (Ga—In—Zn—Sn—O of Ga:In:Zn:Sn=16.8:16.6:47.2:19.4 in atomic % ratio) was formed.

For the deposition of the second oxide semiconductor layer 4B, an In—Zn—Sn—O sputtering target having the ratio shown above was used. For the deposition of the first oxide semiconductor layer 4B, a Ga—In—Zn—Sn—O sputtering target having the ratio shown above was used.

The second oxide semiconductor layer 4B and the first oxide semiconductor layer 4A were formed by DC sputtering method. The apparatus used in the sputtering was “CS-200” available from ULVAC, Inc., and the sputtering conditions were as follows:

### (Sputtering Conditions)

Substrate temperature: room temperature

Film formation power: DC 200 W

Gas pressure: 1 mTorr

Oxygen partial pressure: 100×O₂/(Ar+O₂)=4%

After the laminate of oxide semiconductor layer (4B and 4A) was deposited in the manner described above, patterning was carried out by photolithography and wet etching. “ITO-07N” (a mixed solution of oxalic acid and water) available from Kanto Chemical Co., Inc., was used as an acid-based wet etchant whose temperature was room temperature. It was confirmed in the present Example that all of the oxide thin films subjected to the experimental were appropriately etched without forming etching residues.

After patterning of the oxide semiconductor layer, pre-annealing treatment was carried out to improve the film quality. The pre-annealing was carried out at 350° C. under air atmosphere for 60 minutes.

Then, a source-drain electrode 5 was deposited. Specifically, a pure Mo thin film having a thickness of 100 nm was deposited by a DC sputtering method. The deposition condition of the Mo thin film for a source-drain electrode was the same as that used in the case of the gate electrode described above. The Mo thin film was subsequently patterned by photolithography and wet etching. As an acid-based etchant solution, a mixed acid with a volume ratio of phosphoric acid:nitric acid:acetic acid:water=70:1.9:10:12 (PAN acid) was used as the wet etchant for the wet etching conducted at room temperature. For the purpose of making sure to prevent shunting the source-drain electrode, each of the films was over-etched in the acid-based etchant solution by 50% with respect to the thickness of the electrode 5 to obtain each of the TFT having a channel length of 10 μm and a channel width of 25 μm.

Subsequently, a heat treatment was conducted at 350° C. in air atmosphere for 60 minutes. In another embodiment, a N₂O plasma treatment was conducted at a plasma power of 100 W, a gas pressure of 133 Pa, a treatment temperature of 200° C., and a treatment time of 1 minute, after or instead of the heat treatment.

A passivation layer 6 was formed next. A laminate film (having the total thickness of 250 nm) consisting of SiO₂ (having a thickness of 100 nm) and SiN (having a thickness of 150 nm) was used as the passivation layer 6. The formation of the SiO₂ and SiN films described above was carried out by a plasma CVD method using “PD-220NL” available from SAMCO Inc. In this Example, after plasma pretreatment was carried out for 60 seconds by using N₂O gas, the SiO₂ film and the SiN film were successively formed. The plasma treatment by using N₂O gas was conducted at a plasma power of 100 W, a gas pressure of 133 Pa, and a treatment temperature of 200° C. A mixed gas of N₂O and SiH₄ was used for the formation of the SiO₂ film, and a mixed gas of SiH₄, N₂ and NH₃ was used for the formation of the SiN film. In both cases, the film formation power was set to 100 W and the film formation temperature was set to 200° C.

Then, a contact hole 7 to be used for probing to evaluate transistor characteristics was formed in the passivation layer 6 by photolithography and dry etching.

### [Evaluation of Resistance to Acid-Based Etchant Solution]

Resistance of the oxide semiconductor layer to an acid-based etchant solution was evaluated as shown below.

In the evaluation described below, the first oxide semiconductor was particularly evaluated as it is an oxide semiconductor layer to be subjected to the acid based etchant solution. It is noted here that the oxidation treatment was not conducted for TFTs used for the evaluation so as to confirm an influence of chemical composition (presence/absence of Sn) on the resistance.

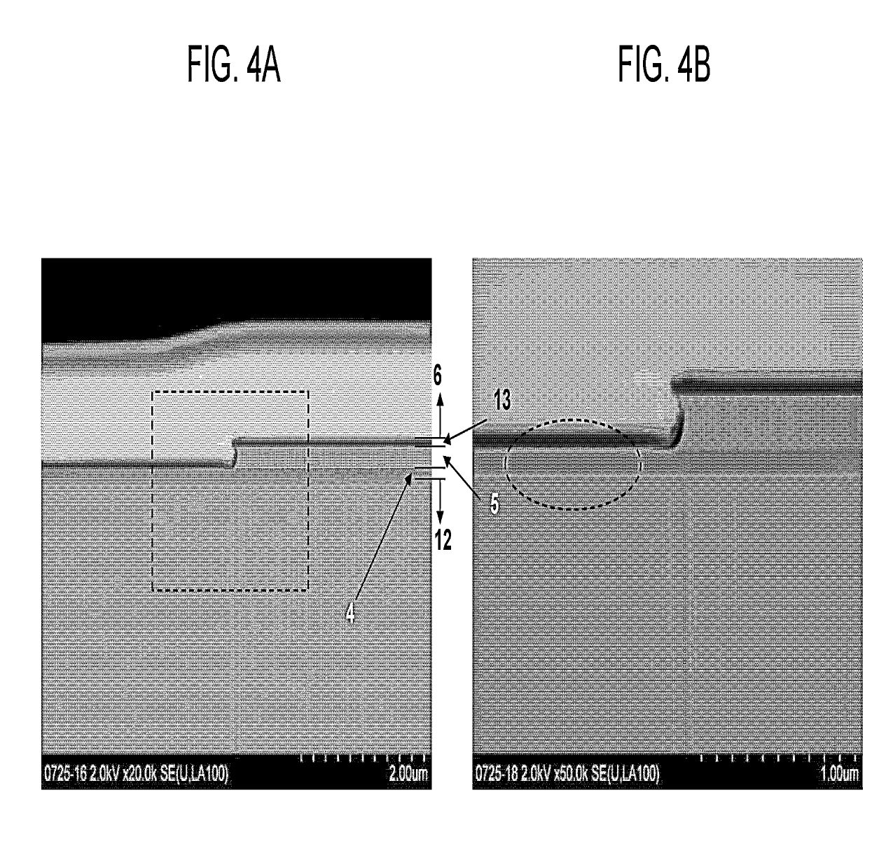

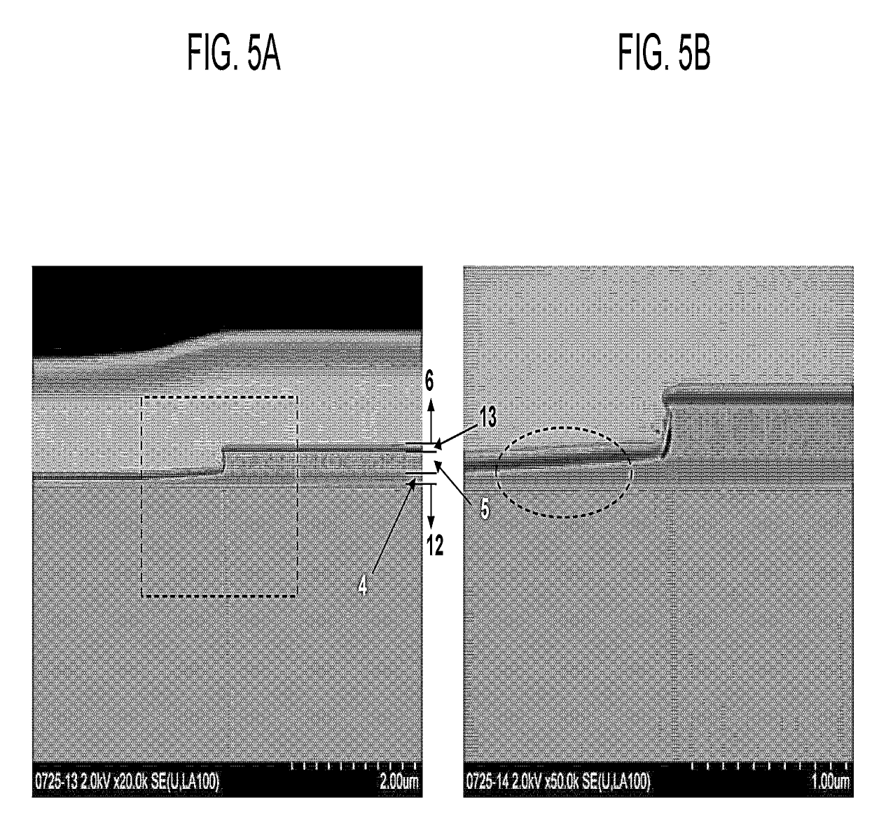

Firstly, a TFT was fabricated in a similar manner to the above-described inventive example with the exceptions of having a single layer of the first oxide semiconductor layer (Ga—In—Zn—Sn—O with the above-described atomic ratio) and not conducting the oxidation treatment. As shown in FIG. 4 and FIG. 5 below, the TFT used for the evaluation was constituted of an oxide semiconductor layer 4 (the single layer of the first oxide semiconductor layer in the present evaluation), a source-drain electrode 5, an evaporated carbon film 13, and a passivation film 6, on a Si substrate 12 in this order. The evaporated carbon film 13 was a protective film imposed for the purpose of observing the sample in an electron microscope, and therefore the carbon film is not an constituting the TFT of the present invention. Another TFT was also fabricated as a comparative example in a similar manner to the above-described inventive example with the exceptions of having a single layer of IGZO (In—Ga—Zn—O, with atomic ratio of In:Ga:Zn=1:1:1. Sn is not included.) as the oxide semiconductor layer and not conducting the oxidation treatment.

Then, a cross section in the lamination direction of each of the obtained TFT was observed by FE-SEM. The pictures of a TFT having an oxide semiconductor layer comprising Sn and a TFT having an oxide semiconductor layer without Sn are shown in FIG. 4 and FIG. 5, respectively.

FIG. 4 shows that thickness of the first oxide semiconductor layer 4 was not decreased by the over-etching in the acid-based etchant solution when the first oxide semiconductor layer 4 comprised Sn. Difference between the thickness of the oxide semiconductor layer 4 directly below an end of a source-drain electrode 5 and the thickness in the center portion of the oxide semiconductor layer 4 (a value in a cross section in the lamination direction of the thin film transistor, as determined by [100×(the thickness of the oxide semiconductor layer directly below a source-drain electrode end−the thickness in the center portion of the first oxide semiconductor layer)/the thickness of the semiconductor layer directly below the source-drain electrode end], the same hereinbelow) was 0%. A TFT comprising an oxide semiconductor layer 4 of excellent in-plane uniformity was obtained, accordingly.

FIG. 5 on the contrary shows that thickness of the first oxide semiconductor layer 4 was decreased by the over-etching in the acid-based etchant solution when the first oxide semiconductor layer 4 did not include Sn. Difference between the thickness of the oxide semiconductor layer 4 directly below an end of a source-drain electrode 5 and the thickness in the center portion of the oxide semiconductor layer 4 was more than 50%.

### [Evaluation of Stress Stability]

For each of the TFTs having a laminate structure of oxide semiconductor of present inventive Example, stress stability was evaluated as shown below.

The stress stability was also evaluated for TFTs of comparative Examples for which the oxidation treatment was not conducted after forming the source-drain electrode 5.

The stress stability was evaluated by a stress application test in which by light irradiation while applying negative bias to the gate electrode. The stress application test conditions were as described below.

Gate voltage: −20 V

Source-drain voltage: 10 V

Substrate temperature: 60° C.

Light stress conditions:
Stress application time: 2 hours
Light intensity: 25,000 NIT
Light source: white LED

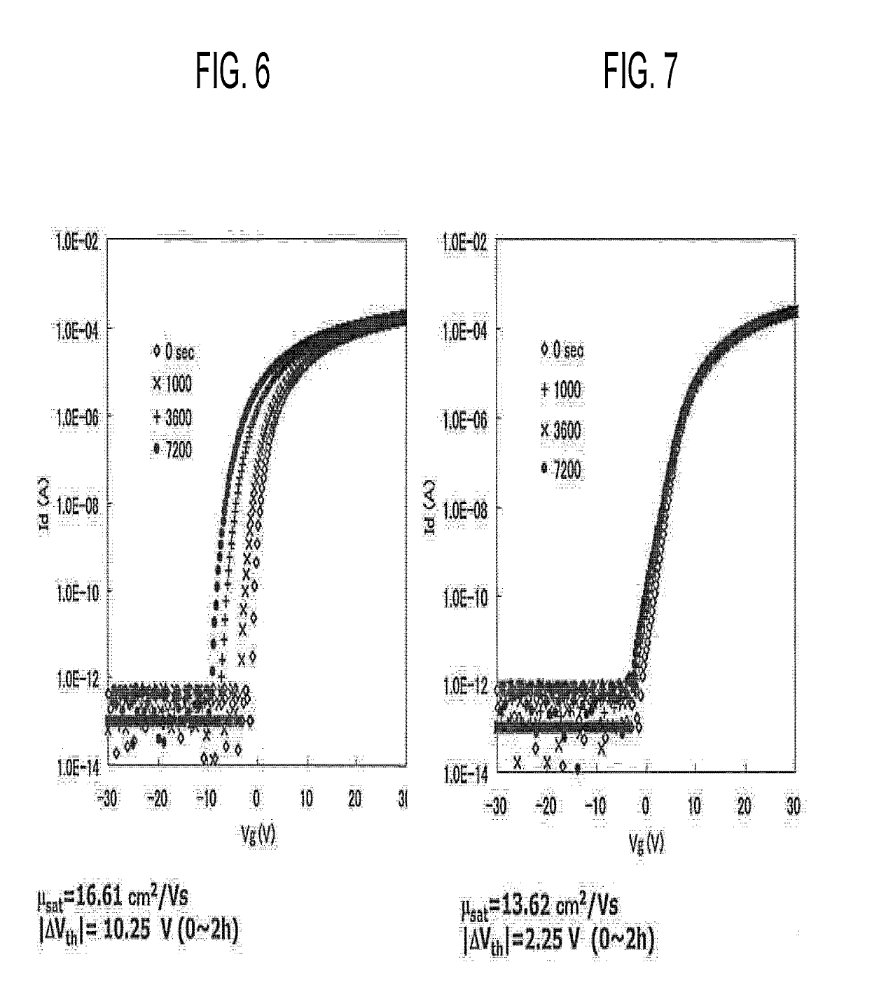

The results are shown in FIG. 6 (a comparative example, without the oxidation treatment) and FIG. 7 (an inventive example, with the oxidation treatment).

The present example can be compared with a comparative example as follows. The comparative example shown in FIG. 6 showed a shift of the threshold voltage toward negative direction with the stress biasing time. The ΔVₜₕ reached 10.25 V in 2 hours. It is considered that the threshold voltage was shifted because holes generated by the light irradiation were driven to and accumulated at the interface between the gate insulator film and the semiconductor as well as at the interface between the back channel of the semiconductor and the passivation film by the application of voltage biasing.

In the case the inventive example, on the other hand, the ΔVₜₕ was 2.25 V in 2 hours as shown in FIG. 7. It was demonstrated that the TFT was superior in terms of the stress stability as the shift of Vₜₕ was much smaller as compared to the comparative example. As the light stress stability ΔVₜₕ is about 3.5 V in a TFT having a conventional a-Si semiconductor layer, it was demonstrated that the shift of threshold voltage was sufficiently small in the present inventive example. It was further demonstrated by the high mobility that a BCE-type TFT having excellent switching characteristics and stress stability was obtained.

Surface analyses of the oxide semiconductor layer by XPS were carried out as described hereinbelow in order to elucidate the reason why the excellent stress stability was achieved by the oxidation treatment as shown above.

### [Surface Analyses of the Oxide Semiconductor Layer by XPS]

Surface analyses of the first oxide semiconductor layer carried out as described below as it is the layer to be subjected to the acid-based etchant solution.

Specifically, TFTs were fabricated in a similar manner to the above-described inventive example with the exception of forming a single layer of Ga—In—Zn—Sn—O as the first oxide semiconductor layer. A heat treatment was conducted for the TFT as the oxidation treatment in an air ambient at 350° C. for 60 minutes.

In the course of the TFT fabrication, the O1s spectrum peak was observed by XPS (X-ray photoelectron spectroscopy) to evaluate each state of the surface of the oxide semiconductor:
(1) immediately after the formation (as-deposited state) of the oxide semiconductor;
(2) immediately after being subjected to wet etching process using the acid etchant and PAN etchant solutions; and
(3) after the oxidation treatment (the heat treatment) after the wet etching (acid etching) explained in (2).

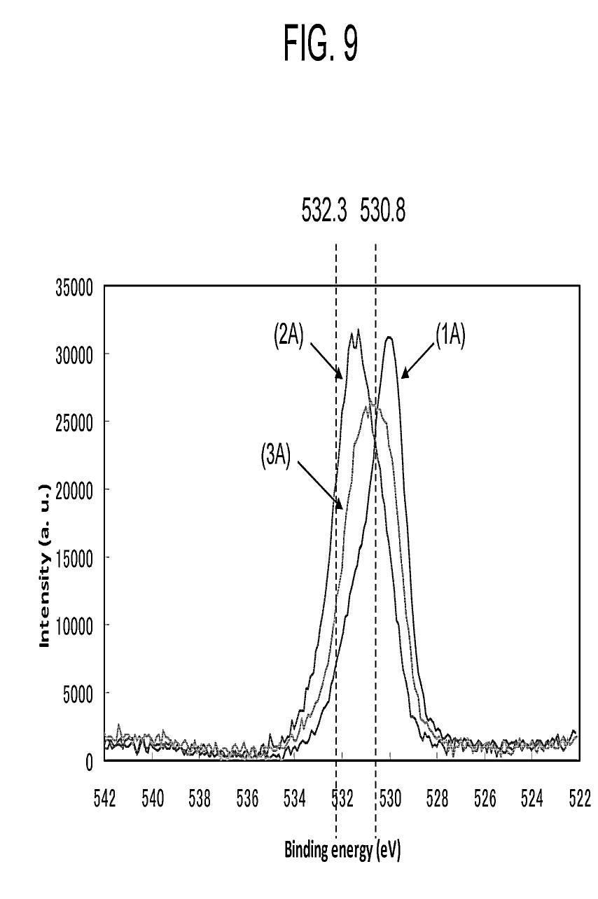

These results are collectively shown in FIG. 8. In FIG. 8, dotted vertical lines at 530.8 eV, 532.3 eV, 533.2 eV respectively indicate oxygen deficiency free O1s spectrum peak, O1s spectrum peak with oxygen deficiency, and O1s spectrum peak of OH group (the same in FIG. 9 and FIG. 10 shown below).

The results shown in FIG. 8 elucidate the following. By comparing positions of the O1s spectrum peak of (1) the as-deposited surface shown by a solid line, (2) the surface after the wet etching (the acid etching) shown by a dotted line, and (3) the surface after the oxidation treatment (the heat treatment) shown by a broken line, the 01s spectrum peak of (1) as-deposited state was at about 530.8 eV while the O1s spectrum peak shifted toward left side of the as-deposited state after the wet etching (the acid etching). However, when the oxidation treatment (the heat treatment) was conducted after (3) the wet etching (acid etching), the O1s spectrum peak was at the same position as the as-deposited surface.

The effect of the oxidation treatment to the state of the surface was found as follows from FIG. 8. The O1s spectrum peak shifted toward left from the as-deposited state in the plot after the wet etching (acid etching). This indicates that by the wet etching (acid etching) contaminants such as OH and C were adsorbed on the surface and bonded to oxygen of metal oxides constituting the oxide semiconductor, forming a state of oxygen deficiency in the oxide semiconductor. By conducting the heat treatment after the wet etching (acid etching), however, the contaminants such as OH and C were substituted by oxygen. The as-deposited state was restored as evident in the O1s spectrum shift by removing OH and C which could be electron traps on the surface. Such behavior of the surface was observed when the N₂O plasma treatment was conducted as the oxidation treatment.

### Example 2

In Example 2, various kinds of source-drain electrodes were investigated particularly in terms of their effects to the S value after the oxidation treatment.

### [Fabrication of TFT]

TFTs were fabricated in a similar manner to those of inventive examples in Example 1 with the exception of forming the source-drain electrode 5 as described below. The oxidation treatment after the formation of the source-drain electrode was conducted as shown in Table 1. The oxidation treatment condition was the same as that of the TFT of the inventive examples in Example 1. The oxide semiconductor layer listed in Table 1 were films having the same composition as the oxide semiconductors 4B (In—Zn—Sn—O) and 4A (Ga—In—Zn—Sn—O) of Example 1. It was confirmed in each of the TFT that the value as determined by [100×(the thickness of the first oxide semiconductor layer directly below a source-drain electrode end−the thickness in the center portion of the first oxide semiconductor layer)/the thickness of the first oxide semiconductor layer directly below the source-drain electrode end] was equal to or smaller than 5% in the lamination direction of the thin film transistor.

### (Formation of Source-Drain Electrode 5)

For the source-drain electrode 5, layers were deposited in either a single layer or a laminate form as shown in Table 1;
Pure Mo single layer (Nos. 1 to 3)
Conductive oxide (IZO) single layer (Nos. 4 to 5)
A laminate of a conductive oxide (IZO) layer and an X1 layer (Al-based layer) or an X2 layer (Barrier metal layer) (Nos. 6 to 9)
A laminate of a pure Mo barrier metal layer and an Al alloy layer (No. 10)

A pure Mo single layer of Nos. 1 to 3 was formed in a thickness of 100 nm in a similar manner to the TFT of an inventive example in Example 1. An IZO (In:Zn=70:30 in mass ratio) film was formed as the conductive oxide layer of Nos. 4 to 9. The thickness of the conductive oxide layer was 20 nm. The layer was deposited by DC sputtering using a target of 101.6 mm in diameter in an input power of DC 200 W, gas pressure of 2 mTorr, and Ar/O₂ gas flow rates of 24/1 sccm. The X1 and X2 layers of Nos. 6 to 9 were deposited by DC sputtering using targets having metal elements constituting the films at room temperature with an input power of 300 W, carrier gas of Ar, and gas pressure of 2 mTorr. The X1 or X2 layer was 80 nm in thickness. The metal layer (barrier metal layer) of 20 nm in thickness and the Al-based layer of 80 nm in thickness of No. 10 sample were deposited by DC sputtering using targets having metal elements constituting the films at room temperature with an input power of 300 W, carrier gas of Ar, and gas pressure of 2 mTorr.

In cases where the source-drain electrode was a laminate, each of the layer shown in “source-drain electrode” column was deposited from left to right immediately on the first oxide semiconductor layer.

For each of the TFTs thus obtained, static characteristics and stress stability were evaluated as shown below.

### [Evaluation of the Static Characteristics (Field-Effect Mobility (Mobility FE), Threshold Voltage Vₜₕ, and S Value)]

Using a prober and a semiconductor parameter analyzer, available from Keithley 4200 SCS, I_{d}-V_{g} characteristics was obtained for each of the TFTs thus obtained under the gate and source-drain electrode voltages shown below.

Gate voltage: −30 to 30 V (increment of 0.25 V)

Source voltage: 0 V

Drain voltage: 10 V

Measurement temperature: room temperature

From the I_{d}-V_{g} characteristics the field-effect mobility (FE), threshold voltage Vₜₕ, and S value were determined. The results are shown in Table 1.

### [Evaluation of Stress Stability]

Stress stability for each of the TFTs was evaluated in the same manner as described in Example 1. The results are shown in Table 1.

If the S value of a TFT was 1.0 or smaller, then it was evaluated “good” while a TFT was evaluated “somewhat good” if the S value was larger than 1.0 in Table 1. If ΔVₜₕ of a TFT was 6 V or smaller, then it was evaluated “good” in terms of stress stability (light stress stability) while the stress stability (light stress stability) was evaluated “somewhat good” if ΔVₜₕ of a TFT was larger than 6 V in Table 1. For the total evaluation, it was rated “very good” if both of the S value and the stress stability were “good”, rated “good” if the S value was “somewhat good” and the stress stability was “good”, and rated “bad” if the S value was “good” and the stress stability was “bad”.

### [Surface Analyses of Oxide Semiconductor Layer by XPS]

As for the Example 1, XPS analyses were carried out for surfaces of the oxide semiconductor including as-deposited state, after the wet etching (acid etching), and after the oxidation treatment (other than No. 1 and No. 4 for which the oxidation treatment was not conducted), and binding energy of the most intensive peak among oxygen 1s spectra (O1s spectrum peak) was determined. If binding energy of the O1s spectrum peak after the oxidation treatment was smaller than that of the peak after the acid etching, then the sample was evaluated as “negative” while binding energy of the O1s spectrum peak after the oxidation treatment was the same as or larger than that of the peak after the acid etching, then the sample was evaluated as “positive.” When the most intensive peak after the oxidation treatment was in the range from 529.0 eV to 531.3 eV, the sample was evaluated “within the range.” On the other hand, when the peak was out of the range, the sample was evaluated “out of the range.” The results are shown in Table 1.

TABLE 1

| | Oxide | Source-drain | | | |
|---|---|---|---|---|---|
| | semiconductor | electrode | | O1s peak | |
| | layer | (Numerical values | | | Peak having specified |
| No. | (First/second) | are in atomic %) | Oxidation treatment | Peak shift | range of binding energy |
| 1 | IGZTO/IZTO | Mo | none | Positive | Out of the range |
| 2 | IGZTO/IZTO | Mo | heat treatment at 350° C. in air | Negative | Within the range |
| 3 | IGZTO/IZTO | Mo | N₂O plasma irradiation | Negative | Within the range |
| 4 | IGZTO/IZTO | IZO | none | Positive | Out of the range |
| 5 | IGZTO/IZTO | IZO | heat treatment at 350° C. in air | Negative | Within the range |
| 6 | IGZTO/IZTO | IZO/Al | heat treatment at 350° C. in air | Negative | Within the range |
| 7 | IGZTO/IZTO | IZO/Mo/Al | heat treatment at 350° C. in air | Negative | Within the range |
| 8 | IGZTO/IZTO | IZO/Mo/Al/Mo | heat treatment at 350° C. in air | Negative | Within the range |
| 9 | IGZTO/IZTO | IZO/Al—0.1Ni—0.5Ge—0.2La | heat treatment at 350° C. in air | Negative | Within the range |
| 10 | IGZTO/IZTO | Mo/Al—3Ni—0.6Nd/Mo | heat treatment at 350° C. in air | Negative | Within the range |

| | | | | | Stress stability | | |
|---|---|---|---|---|---|---|---|
| | | Threshold | S value | | to light | | |
| | Mobility | voltage | S value | | ΔVₜₕ | | Total |
| No. | (cm²/Vs) | Vₜₕ (V) | (V/decade) | Evaluation | (V) | Evaluation | evaluation |
| 1 | 16.6 | 0.0 | 0.35 | Good | 10.3 | Bad | Bad |
| 2 | 14.4 | 2.5 | 1.12 | Somewhat | 3.3 | Good | Good |
| | | | | good | | | |
| 3 | 13.6 | 2.0 | 1.05 | Somewhat | 2.3 | Good | Good |
| | | | | good | | | |
| 4 | 15.1 | 1.5 | 0.33 | Good | 11.0 | Bad | Bad |
| 5 | 14.6 | 3.0 | 0.28 | Good | 4.5 | Good | Very good |
| 6 | 14.2 | 3.1 | 0.31 | Good | 4.3 | Good | Very good |
| 7 | 14.5 | 2.4 | 0.25 | Good | 4.3 | Good | Very good |
| 8 | 14.0 | 2.8 | 0.27 | Good | 4.0 | Good | Very good |
| 9 | 15.3 | 3.0 | 0.29 | Good | 4.8 | Good | Very good |
| 10 | 14.2 | 2.3 | 1.09 | Somewhat | 2.5 | Good | Good |
| | | | | good | | | |

The results shown in Table 1 can be summarized as follows. Firstly, the static characteristics are described.

Among the samples in which the source-drain electrode (Nos. 1 to 3) was a pure Mo layer as shown in Table 1, sample No. 1 which was not subjected to the oxidation treatment showed low S value. The O1s spectrum peak of the oxide semiconductor surface did not show the shift toward lower binding energy as compared to that of after the acid etching, demonstrating insufficient restoration of the oxygen deficiency and poor stress stability. The S values were increased for samples No. 2 and 3 which were subjected to the oxidation treatment.

By comparing the results of No. 1 and No. 2 in Table 1, it can be seen that the S value was increased when the heat treatment in air was conducted for the samples in which the source-drain electrode consisted of a pure Mo layer. Higher bias voltage is necessary to modulate the drain current when the S value is increased. The increase of S value indicates deterioration of the static characteristics, accordingly.

On the other hand, for the samples No. 4 and No. 5 in which an IZO conductive oxide layer was used for the source-drain electrode and the conductive oxide layer was in direct contact to the oxide semiconductor layer as indicated in Table 1, the S value did not change regardless of the heat treatment in air, indicating their S values were small. As sample No. 4 was not subjected to the oxidation treatment, the O1s spectrum peak of the first oxide semiconductor surface did not show the shift toward lower binding energy as compared to the peak of the first oxide semiconductor subjected to the acid etching. Recovery of the oxygen deficiency on the surface was not sufficient and the stress stability was poor in the sample.

The increase of S value shown in sample No. 2 is considered to be due to deterioration of electrical conduction at the end of Mo source-drain electrode which was oxidized by the heat treatment in air. When, on the other hand, a conductive oxide such as IZO was used for the source-drain electrode, there may be little change in electrical conductivity by the oxidation (heat treatment), and hence deterioration of the static characteristics was presumably suppressed.

Nos. 6 to 9 were examples in which a metal film such as a pure Mo and an Al-based layer was laminated on the conductive oxide layer as the source-drain electrode. In these cases, the S value did not increase after the oxidation treatment, demonstrating excellent static characteristics.

Sample No. 10 is an example in which the source-drain electrode was a laminate of a barrier metal layer (pure Mo film) and an Al alloy layer. It is evident by comparing No. 10 to No. 2 whose S value was 1.12 V/decade that increase of S values by the oxidation treatment was circumvented as S value was decreased to 1.09 V/decade after the oxidation treatment. It is considered that the increase of S value was suppressed by adopting the laminate structure for the source-drain electrode as well as reducing the thickness of the pure Mo film constituting the laminate. In such a configuration, the Al alloy layer provides sufficient protection to the barrier layer, resulting in suppression of oxidation of end portion of the pure Mo film despite of the oxidation treatment.

Results of stress stability are described next. By comparing the results of No. 4 and Nos. 5 to 10 in Table 1, it was found that, by using a conductive oxide for a part of the source-drain electrode which was to be in contact to the oxide semiconductor as for Nos. 5 to 10, amount of threshold voltage shift (ΔVₜₕ) was improved as compared to No. 4 for which the heat treatment in air was not carried out. The improvement of ΔVₜₕ as compared to No. 4 was also realized by adopting a laminate film consisting of a barrier metal layer and an Al alloy layer for the source-drain electrode as well as conducting a heat treatment in air after forming the source-drain electrode as for Nos. 5 to 10.

From these results, it was elucidated that both excellent static characteristics and superior stress stability can be surely secured either by utilizing a conductive oxide to a portion in contact to the oxide semiconductor in the source-drain electrode or by making the source-drain electrode a laminate of a barrier metal layer and an Al alloy layer and conducting a heat treatment in air after forming the source-drain electrode.

### Example 3

Effect of heat treatment temperature (heating temperature) to recovery of the oxygen deficiencies was studied for the case where a heat treatment is conducted as the oxidation treatment.

### [Fabrication of TFT]

TFTs were fabricated in a similar manner to Example 1 with the exceptions of; a thin film for the source-drain electrode 5 was formed as shown below; an oxidation treatment was carried out after the formation of the source-drain electrode as described below; and a passivation film 6 was formed as explained below.

A pure Mo film (a pure Mo electrode) or an IZO (In—Zn—O) thin film (an IZO electrode) was used for the source-drain electrode 5. Chemical composition of the IZO thin film was In:Zn=90:10 in mass ratio. The pure Mo film or the IZO thin film was deposited to a thickness of 100 nm by DC sputtering method using a Mo sputtering target or an IZO sputtering target. Deposition conditions for each electrode were as follows.
(Deposition of pure Mo film (pure Mo electrode))
Input power (deposition power): DC 200 W, gas pressure: 2 mTorr, gas flow rate:
Ar 20 sccm, substrate temperature (deposition temperature): room temperature
(Deposition of IZO film (IZO electrode))
Input power (deposition power): DC 200 W, gas pressure: 1 mTorr, gas flow rate:
Ar 24 sccm and O₂ 1 sccm, substrate temperature (deposition temperature): room temperature.

A heat treatment was conducted at 300 to 600° C. in air atmosphere for 60 minutes as the oxidation treatment after the formation of the source-drain electrode. Comparative samples for which the heat treatment was not carried out were also prepared.

A laminate film (having the total thickness of 250 nm) consisting of SiO₂ (having a thickness of 100 nm) and SiN (having a thickness of 150 nm) was used as the passivation film 6. The formation of the SiO₂ and SiN films described above was carried out by a plasma CVD method using “PD-220NL” available from SAMCO Inc. A mixed gas of N₂O and SiH₄ was used for the formation of the SiO₂ film, and a mixed gas of SiH₄, N₂ and NH₃ was used for the formation of the SiN film. The film formation temperatures were set to 230° C. and 150° C., respectively. In both cases, the film formation power was set to RF 100 W.

Samples for analyses were prepared using the fabricated TFTs as described hereinbelow. Influences of heat treatment temperature on bonding state of oxygen at a surface of the first oxide semiconductor layer and the surface layer of the first oxide semiconductor layer were investigated.

### [XPS Analyses of Surface of Oxide Semiconductor Layer]

It is the first oxide semiconductor layer that is subjected to an acid-based etchant solution as explained in Example 1. Surface of the first oxide semiconductor was therefore analyzed in the following for the purpose of investigating relationship between the oxygen bonding state at the surface of the first oxide semiconductor and heat treatment temperature in the course of the TFT fabrication.

Specifically, samples 1 and 2 for analyses having a single layer of first oxide semiconductor layer were prepared as described in the following. The surface analyses of the first oxide semiconductor layer of the samples 1 and 2 were conducted by using XPS and their O1s spectra were investigated.

In this study of the O1s spectrum, surface of the oxide semiconductor (1A) before being subjected to an acid etchant solution, (2A) after being subjected to an acid etchant solution, and (3A) after a heat treatment of (2A) as the oxygen deficiencies at the surface are induced by immersing the first oxide semiconductor to the acid etchant solution as explained above.

Sample 1 for analyses (a pure Mo electrode was used for the source-drain electrode)

After depositing a Ga—In—Zn—Sn—O oxide semiconductor layer of 100 nm in thickness on a silicon substrate, a heat treatment (pre-annealing) was conducted in air at 350° C. for 1 hour (1A). Subsequently, a pure Mo film of 100 nm in thickness was deposited as a source-drain electrode on the oxide semiconductor layer. Then the pure Mo film was completely removed by using a PAN etchant solution (2A). After that, a heat treatment (oxidation treatment) was carried out in air at 350° C. for 1 hour (3A). The XPS analyses were conducted for each of the sample which proceeded to the steps of (1A), (2A), and (3A).

Sample 2 for analyses (an IZO electrode was used for the source-drain electrode) After depositing a Ga—In—Zn—Sn—O oxide semiconductor layer of 100 nm in thickness on a silicon substrate, a heat treatment (pre-annealing) was conducted in air at 350° C. for 1 hour (1A). Subsequently, an IZO thin film of 100 nm in thickness was deposited as a source-drain electrode on the oxide semiconductor layer. Then the IZO thin film was completely removed by using a PAN etchant solution (2A). After that, a heat treatment (oxidation treatment) was carried out in air for 1 hour at 350° C., 500° C., and 600° C. (3A). The XPS analyses were conducted for each of the sample which proceeded to the steps of (1A), (2A), and (3A).

XPS data acquired from the samples 1 and 2 for analyses are shown in FIG. 9 and FIG. 10, respectively.

Followings were found from FIG. 9. The O1s spectrum peak was located at 530.0 eV before the etching treatment (1A), indicating small density of oxygen deficiency on the oxide semiconductor surface. When the etching treatment was carried out (2A), the spectrum peak was shifted toward high binding energy to 531.5 eV. It can be considered that oxygen deficiencies were increased by way of the wet etching (acid etching) on the surface of the oxide semiconductor. When the heat treatment at 350° C. was conducted after the etching treatment (3A), the spectrum peak was shifted again toward low binding energy of about 530.8 eV. It can be deduced from these results that the oxygen deficiencies induced by the etching treatment were partially recovered by the heat treatment after the etching treatment.

Further, followings were found from FIG. 10. When an IZO electrode was used for the source-drain electrode, the O1s spectrum peak was located at 530.0 eV before the etching treatment (1A) as for FIG. 9. When the etching treatment was carried out (2A), the spectrum peak was shifted toward high binding energy to 531.4 eV. It was found that oxygen deficiencies were increased by way of the wet etching (acid etching) on the surface of the oxide semiconductor. When the heat treatment was conducted at either 350° C. or 500° C. after the etching treatment (3A), the spectrum peak, showing little shift in terms of binding energy, changed its profile so to have a shoulder peak in the vicinity of 530.8 eV. The relative increase of the peak around 530.8 eV indicating the state of lower extent of the oxygen deficiency suggested that a portion of oxygen deficiencies were restored by the heat treatment at 350° C. or 500° C. after the etching treatment. Further, when the heat treatment was conducted at 600° C. after the etching treatment (3A), the main component of the spectrum peak was at 530.8 eV, showing further decrease of the oxygen deficiencies by elevating the heat treatment temperature from 500° C. to 600° C. It is therefore considered effective to increasing the heat treatment temperature in order to enhance the reliability of the transistor when an IZO electrode was used for the source-drain electrode.

### [Measurement of Distribution of Chemical Contents on the Surface of the First Oxide Semiconductor Layer (Presence/Absence of Zn Concentrated Layer)]

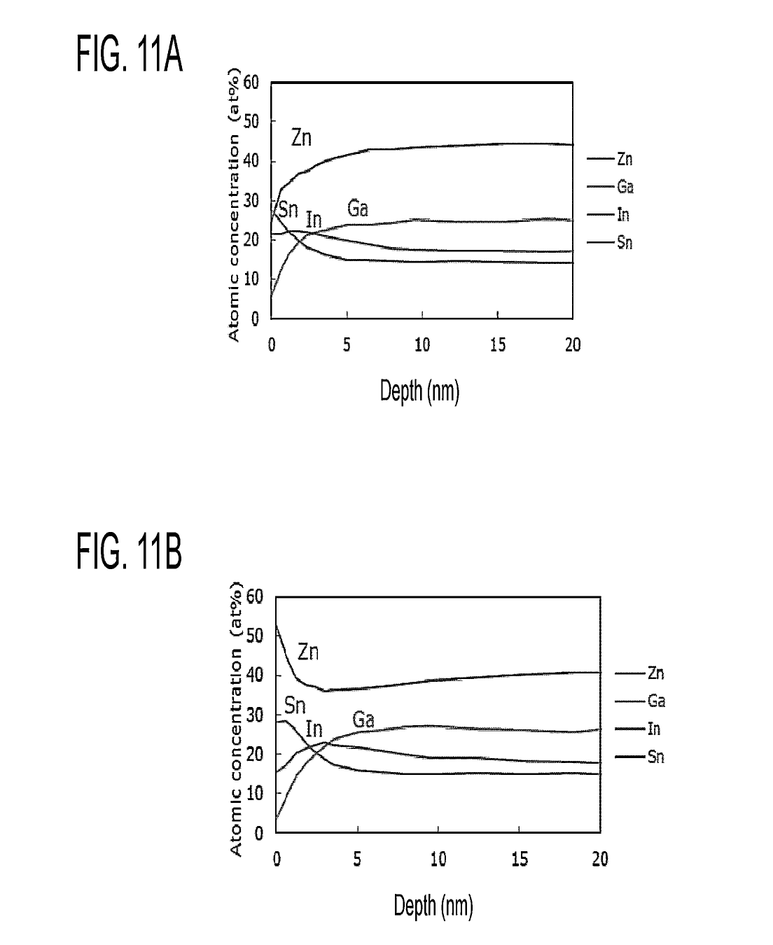

Distribution of chemical contents on the surface of the first oxide semiconductor layer was investigated by using XPS. For the analyses, the samples 2 used for evaluation of the oxygen bonding state were used after being subjected to the heat treatment at 600° C. to (2A) and (3A) states, respectively. Specifically, respective content of Zn, Sn, In, and Ga relative to the total amount of all the metal elements in the first oxide semiconductor was measured from the surface to the thickness direction. Results of the measurements after the acid etching (2A) and after the acid etching followed by the heat treatment (3A) are shown in FIG. 11A and FIG. 11B, respectively.

It was revealed from the result shown in FIG. 11A that the concentrations of Zn, Ga, and Sn were significantly different depending on the depth. Particularly, the concentrations of Zn and Ga in the surface layer were much smaller than those in the inner layer (meaning about 10 to 20 nm in depth from the surface, the same hereinafter) of the first oxide semiconductor layer. On the contrary to the results shown in FIG. 11A, Zn concentration in the surface layer was increased as compared to that in the inner layer after being subjected to the acid treatment followed by the heat treatment at 600° C. (3A). The ratio of the Zn concentration in the surface layer was 1.39 in FIG. 11B.

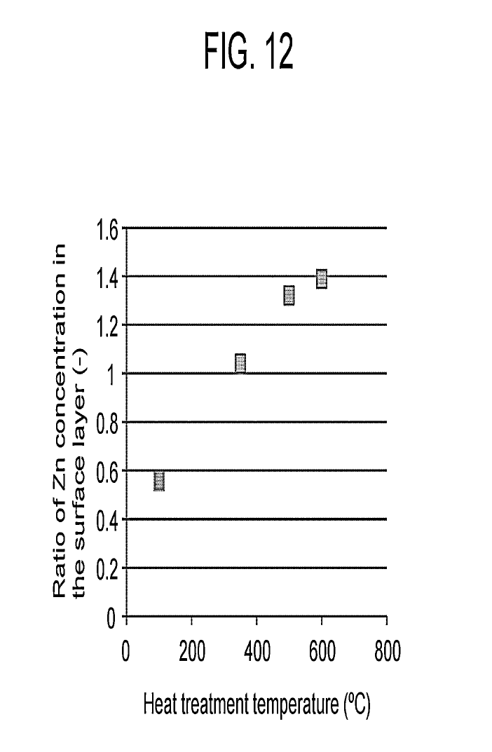

Next, temperature of the heat treatment after the acid etching was varied to 100° C., 500° C., 350° C., and 600° C. A relation between the ratio of the Zn concentration in the surface layer and the heat treatment temperature is plotted in FIG. 12.

It was revealed from the result shown in FIG. 12 that the Zn concentration in the surface layer of the first oxide semiconductor layer increased with the heat treatment temperature. It is considered that diffusion of Zn to the surface and the oxidation of the surface of the first oxide semiconductor was enhanced (the oxygen deficiency was recovered) by increasing the heat treatment temperature as shown in FIG. 10. Increasing the heat treatment temperature is thus considered effective to improve the reliability of TFTs.

### EXPLANATION OF REFERENCE NUMERALS

1 Substrate

2 Gate electrode

3 Gate insulator film

4 Oxide semiconductor layer

4A First oxide semiconductor layer

4B Second oxide semiconductor layer

5 Source-drain (S/D) electrode

6 Passivation film (insulating film)

7 Contact hole

8 Transparent conductive film

9 Etch stopper layer

11 Conductive oxide layer

X X layer

X1 X1 layer

X2 X2 layer

12 Si substrate

13 Evaporated carbon film

1. A thin film transistor comprising;
a gate electrode, a gate insulator film, an oxide semiconductor layer, a source-drain electrode, and a passivation film to protect the source-drain electrode, on a substrate in this order,
the oxide semiconductor layer is a laminate comprising:
a first oxide semiconductor layer consisting of Sn; In; and at least one of Ga and Zn; and O; and
a second oxide semiconductor layer consists of one or more kinds of element selected from the group consisting of In, Zn, Sn, and Ga; and O,
wherein
the second oxide semiconductor layer is formed on the gate insulator film;
the first oxide semiconductor layer is formed between the second oxide semiconductor layer and the passivation film or between the second oxide semiconductor layer and the source-drain electrode; and
a value in a cross section in the lamination direction of the thin film transistor, as determined by [100×(the thickness of the first oxide semiconductor layer directly below a source-drain electrode end−the thickness in the center portion of the first oxide semiconductor layer)/the thickness of the first semiconductor layer directly below the source drain electrode end] is equal to or smaller than 5%.

2. The thin film transistor according to claim 1, wherein binding energy of the most intensive peak among oxygen is spectra is in a range from 529.0 eV to 531.3 eV when a surface of the oxide semiconductor layer is subjected to X-ray photoelectron spectroscopy.

3. The thin film transistor according to claim 1, wherein content of Sn relative to the total amount of all the metal elements in the first oxide semiconductor layer is larger than or equal to 5 atomic % and smaller than or equal to 50 atomic %.

4. The thin film transistor according to claim 1, wherein
the first oxide semiconductor layer is composed of In, Ga, Zn, Sn, and O, and
the contents of respective metal elements relative to the total amount of In, Ga, Zn, and Sn; are
In: larger than or equal to 15 atomic % and smaller than or equal to 25 atomic %;
Ga: larger than or equal to 5 atomic % and smaller than or equal to 20 atomic %;
Zn: larger than or equal to 40 atomic % and smaller than or equal to 60 atomic %; and
Sn: larger than or equal to 5 atomic % and smaller than or equal to 25 atomic %.

5. The thin film transistor according to claim 1, wherein
the first oxide semiconductor layer comprises Zn, and a concentration of Zn (in atomic %) at a surface is 1.0 to 1.6 times of the content of Zn (in atomic %) in the first oxide semiconductor layer.

6. The thin film transistor according to claim 1, wherein the source-drain electrode comprises a conductive oxide layer which is in direct contact to the first oxide semiconductor layer.

7. The thin film transistor according to claim 6, wherein
the source-drain electrode is composed of a laminate structure consisting of
the conductive oxide layer and
X layer which is one or more metal layers comprising one or more kinds of element selected from a group consisting of Al, Cu, Mo, Cr, Ti, Ta, and W,
from a side of the oxide semiconductor layer.

8. The thin film transistor according to claim 7, wherein
the X layer is composed of a laminate structure consisting of;
X2 layer, a metal layer comprising one or more kinds of element selected from a group consisting of Mo, Cr, Ti, Ta, and W; and
X1 layer, a metal layer comprising one or more kinds of layer selected from a group consisting of a pure Al layer, an Al alloy layer, a pure Cu layer, and a Cu alloy layer;
in that order from a side of the oxide semiconductor layer.

9. The thin film transistor according to claim 7, wherein
the metal layer (X layer) is composed of a laminate structure consisting of;
X1 layer, a metal layer comprising one or more kinds of layer selected from a group consisting of a pure Al layer, an Al alloy layer, a pure Cu layer, and a Cu alloy layer; and
X2 layer, a metal layer comprising one or more kinds of element selected from a group consisting of Mo, Cr, Ti, Ta, and W;
in that order from a side of the oxide semiconductor layer.

10. The thin film transistor according to claim 7, wherein
the metal layer (X layer) is composed of a laminate structure consisting of;
X2 layer, a metal layer comprising one or more kinds of element selected from a group consisting of Mo, Cr, Ti, Ta, and W;
X1 layer, a metal layer comprising one or more kinds of layer selected from a group consisting of a pure Al layer, an Al alloy layer, a pure Cu layer, and a Cu alloy layer; and
X2 layer, a metal layer comprising one or more kinds of element selected from a group consisting of Mo, Cr, Ti, Ta, and W;
in that order from a side of the oxide semiconductor layer.

11. The thin film transistor according to claim 7, wherein
the Al alloy layer comprises one or more kinds of element selected from a group consisting of Ni, Co, Cu, Ge, Ta, Mo, Hf, Zr, Ti, Nb, W, and a rare-earth element in an amount of 0.1 atomic % or more.

12. The thin film transistor according to claim 6, wherein
the conductive oxide layer comprises one or more kinds of element selected from a group consisting of In, Ga, Zn, and Sn; and O.

13. The thin film transistor according to claim 1, wherein
the source-drain electrode is composed of a laminate structure consisting of
a barrier metal layer comprising one or more kinds of element selected from a group consisting of Mo, Cr, Ti, Ta, and W; and
an Al alloy layer,
in this order from a side of the oxide semiconductor layer.

14. The thin film transistor according to claim 13, wherein
the barrier metal of the source-drain electrode comprises pure Mo or a Mo alloy.

15. The thin film transistor according to claim 13, wherein
the Al alloy layer of the source-drain electrode comprises one or more kinds of element selected from a group consisting of Ni and Co in a total amount of 0.1 to 4 atomic %.

16. The thin film transistor according to claim 13, wherein
the Al alloy layer of the source-drain electrode comprises one or more kinds of element selected from a group consisting of Cu and Ge in a total amount of 0.05 to 2 atomic %.

17. The thin film transistor according to claim 15, wherein
the Al alloy layer of the source-drain electrode further comprises one or more kinds of element selected from a group consisting of Nd, Y, Fe, Ti, V, Zr, Nb, Mo, Hf, Ta, Mg, Cr, Mn, Ru, Rh, Pd, Ir, Pt, La, Gd, Tb, Dy, Sr, Sm, Ge, and Bi.

18. A manufacturing method of the thin film transistor according to claim 1, wherein
the source-drain electrode formed on the oxide semiconductor layer is pattered by using an acid-based etchant solution, and then,
an oxidation treatment is conducted for at least a part of the oxide semiconductor layer which is subjected to the acid-based etchant solution, and then
the passivation film is formed.

19. The manufacturing method of the thin film transistor according to claim 18, wherein the oxidation treatment is at least one of a heat treatment and a N₂O plasma treatment.

20. The manufacturing method of the thin film transistor according to claim 19, wherein the oxidation treatment is conducted both of the heat treatment and the N₂O plasma treatment.

21. The manufacturing method of the thin film transistor according to claim 19 wherein the heat treatment is conducted at a temperature higher than or equal to 130° C. and lower than or equal to 700° C.

22. The manufacturing method of the thin film transistor according to claim 21 wherein the heat treatment is conducted at a temperature higher than or equal to 250° C.
